(19) United States
(12) Patent Application Publication
(10) Pub. No.: US 2009/0259335 A1
(43) Pub. Date: Oct. 15, 2009

(54) Substrate Processing System

(75) Inventors: Gaku Ikeda, Yamanashi-Ken (JP); Keiji Osada, Yamanashi-Ken (JP); Kunio Takano, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: TOKYO ELECTRON LIMITED, Minato-ku, Tokyo (JP)

(21) Appl. No.: 12/085,572

(22) PCT Filed: Nov. 28, 2006
(86) PCT No.: PCT/JP2006/323734

§ 371 Date: May 28, 2008

(30) Foreign Application Priority Data
Nov. 28, 2005 (JP) 2005-342433

(51) Int. Cl. H01L 21/677

(52) U.S. Cl. 700/228

(57) ABSTRACT

When a wafer (W101) to be returned from a second cluster (12) to a first cluster (10) is delivered to a pass area (PA), a vacuum transfer robot (RB1) in the first cluster (10) performs serial transportation in the first cluster (10) preferentially while keeping the wafer (W101) at the pass area (PA). Subsequently, the vacuum transfer robot (RB1), holding a wafer (W104) to be sent from the first cluster (10) to the second cluster (12) by one arm thereof, receives the wafer (W101) existing in the pass area (PA) by the other arm thereof and delivers the wafer (W104) to the pass area (PA) instead, through pick and place operation. According to the procedure, throughput of continuous processing employing a plurality of process modules of two clusters (multi-chamber apparatuses) (10, 12) is improves as much as possible.

### TECHNICAL FIELD

The present invention relates to a substrate processing system of a multi-chamber type, and more particularly to a substrate processing system having two multi-chamber apparatuses connected in series.

### BACKGROUND ART

In the technical field of the semiconductor manufacturing system, there has been employed a multi chamber system in which a plurality of process modules are arranged around a main transfer chamber to perform a plurality of semiconductor manufacturing steps collectively.

In general, in a substrate processing system of a multi chamber type for vacuum processes, or a so-called cluster tool, a transfer chamber located at the center of the cluster, as well as chambers of process modules, is kept under a vacuum state. A loadlock chamber, which is an interface module, is connected to the transfer chamber via a gate valve. A process object such as a semiconductor wafer is transferred into the loadlock chamber under the atmospheric pressure, and subsequently is transferred from the loadlock chamber, having been put into a reduced-pressure state, into the transfer chamber. A transfer mechanism installed within the transfer chamber transfers a semiconductor wafer removed from the loadlock chamber into a first process module. This process module performs a process as a first step according to a preset recipe, consuming a predetermined time. After completion of the process as the first step, the transfer mechanism in the transfer chamber removes the semiconductor wafer from the first process module, and then transfers it into a second process module. Also in the second process module, a process as a second step is performed according to a preset recipe, consuming a predetermined time. After completion of the process as the second step, the transfer mechanism in the transfer chamber removes the semiconductor wafer from the second process module, and thereafter, if there is a following step, the transfer mechanism transfers the semiconductor wafer into a third process module; if there is no following step, the transfer mechanism returns the semiconductor wafer to the loadlock module. In a case where a process is performed in a third or further process module, if there is a following step, the semiconductor wafer is transferred into a further process module; if there is no following step, the transfer mechanism returns the semiconductor wafer to the loadlock module. When the semiconductor wafer having been subjected to a series of processes employing a plurality of process modules in the aforementioned manner, the loadlock chamber is switched from a reduced-pressure state to an atmospheric-pressure state. Thereafter, the semiconductor wafer is removed from the loadlock chamber via a wafer entrance/exit port on a side opposite to the transfer chamber.

In a substrate processing system of a tandem type in which two multi-chamber apparatuses connected in series, a transfer chamber of a first cluster with a loadlock chamber and a transfer chamber of a second cluster without a loadlock chamber are connected via a gate valve, and a relay unit is provided to transfer a semiconductor wafer between the transfer mechanisms of the transfer chambers (see JP2004-119635A, notably FIG. 3). A typical example of a transfer sequence is as follows. A first transfer mechanism of the first cluster sequentially transfers each semiconductor wafer introduced from the loadlock chamber to one or more of process modules in the first cluster in order for the semiconductor wafer to be subjected to a first phase processing comprising one or more steps, and transfer the semiconductor wafer to the relay unit after the completion of the processes. A second transfer mechanism of the second cluster receives the semiconductor wafer kept in the relay unit, sequentially transfers the semiconductor wafer to one or more of process modules in the second cluster in order for the semiconductor wafer to be subjected to a second phase processing comprising one or more steps, and returns the semiconductor wafer to the relay unit after the completion of the processes. The first transfer mechanism is receives the processed semiconductor wafer and returns it to the loadlock chamber.

As mentioned above, a substrate processing system of a tandem type having two clusters connected in series can continuously perform one or more processes by the first cluster and one or more processes by the second cluster. In addition, since the atmosphere in the first cluster and the atmosphere in the second cluster can be separated by a gate valve, cross contamination (transfer or diffusion of contamination) can advantageously be suppressed.

In the aforementioned processing system of the tandem type, a semiconductor wafer to be transferred from the first cluster to the second cluster and a semiconductor wafer to be transferred from the second cluster to the first cluster are kept in a common relay unit in different time frames.

It was considered that it is not preferable to keep a semiconductor wafer to be transferred from one cluster to the other cluster waiting in the relay unit, since whole wafer transferring in the system clogs at the relay unit. Thus, immediately after a semiconductor wafer is delivered to the relay unit from the second transfer mechanism of the second cluster, the first transfer mechanism of the first cluster receives the semiconductor wafer; and immediately after a semiconductor wafer is delivered to the relay unit from the first transfer mechanism of the first cluster, the second transfer mechanism of the second cluster receives the semiconductor wafer.

However, such a transfer sequence, in which receipt of a wafer from the relay unit is preferentially performed, causes reduced throughput of the whole processing system, or reduced throughput for a whole process lot. That is, in a case wherein the highest priority is placed on throughput of the whole processing system, in serial transfer operation that transfers each semiconductor wafer to and from a plurality of process modules according to the process-step order both in the first cluster and the second cluster, an interchanging transfer method in which, at each process module, a semiconductor wafer having been just processed in the process module is removed from the process module, and into the process module a next semiconductor wafer having been just removed from a process module for a preceding process step is transferred, is considered to be most advantageous. Conventionally, even in a serial transfer operation, a semiconductor wafer, which is delivered from the transfer mechanism of one cluster to the relay unit, is immediately removed by the transfer mechanism of the other cluster to be transferred to the next destination. However, if the receipt of the semiconductor wafer and the transfer to the next destination are performed preferentially, the transferring of wafers to and from the process modules are postponed, and as a result, throughput of the whole processing system, or throughput for a whole process lot is reduced.

### SUMMARY OF THE INVENTION

The present invention solves the foregoing problems associated with the prior art, and the object of the present invention is to provide a substrate processing system that improves throughput of continuous processing employing a plurality of process modules of both two multi-chamber apparatuses.

In order to attain the above objective, according to a first aspect of the present invention, there is provided a substrate processing system wherein: the system is provided with a first multi-chamber apparatus and a second multi-chamber apparatus which are connected in series; the first multi-chamber apparatus includes a first transfer mechanism, a first group of process modules arranged in an surrounding area of the first transfer mechanism, and an interface module disposed in the surrounding area of the first transfer mechanism to transfer process objects between the first multi-chamber apparatus and an exterior thereof; the second multi-chamber apparatus includes a second transfer mechanism, and a second group of process modules arranged in an surrounding area of the second transfer mechanism; a relay unit is disposed between the first transfer mechanism and the second transfer mechanism to temporarily keep a process object in order to transfer the process object between the first transfer mechanism and the second transfer mechanism; and the substrate processing system is further provided with a controller, which is configured to control the first and second transfer mechanisms such that the first and second transfer mechanisms sequentially transfers each process object to process modules of the first and second groups according to a predetermined process sequence, and such that, at each process module of the first and second groups, the first and second transfer mechanisms respectively carry a process object, which has been processed in that process module, out of that process module and carry another process object, which is to be processed next in that process module, into that process module instead; characterized in that controller is configured to control the first transfer mechanism such that, when a first process object having been subjected to predetermined process or processes in the second multi-chamber apparatus is carried into the relay unit by the second transfer mechanism, if there is established a state where a second process object, which is to be carried from the first multi-chamber apparatus into the second multi-chamber apparatus next, can not be carried into the relay unit, the first process object is kept suspended in the relay unit until there is established a state where the second process object can be carried into the relay unit, and thereafter the first transfer mechanism carries the first process object out of the relay unit and carries the second process object into the relay unit instead.

In addition, according to a second aspect of the present invention, there is provided a substrate processing system wherein: the system is provided with a first multi-chamber apparatus and a second multi-chamber apparatus which are connected in series; the first multi-chamber apparatus includes a first transfer mechanism, a first group of process modules arranged in an surrounding area of the first transfer mechanism, and an interface module disposed in the surrounding area of the first transfer mechanism to transfer process objects between the first multi-chamber apparatus and an exterior thereof; the second multi-chamber apparatus includes a second transfer mechanism, and a second group of process modules arranged in an surrounding area of the second transfer mechanism; a relay unit is disposed between the first transfer mechanism and the second transfer mechanism to temporarily keep a process object in order to transfer the process object between the first transfer mechanism and the second transfer mechanism; and the substrate processing system is further provided with a controller, which is configured to control the first and second transfer mechanisms such that the first and second transfer mechanisms sequentially transfers each process object to process modules of the first and second groups according to a predetermined process sequence, and such that, at each process module of the first and second groups, the first and second transfer mechanisms respectively carry a process object, which has been processed in that process module, out of that process module and carry another process object, which is to be processed next in that process module, into that process module instead; characterized in that controller is configured to control the second transfer mechanism such that, when a first process object having been subjected to predetermined process or processes in the first multi-chamber apparatus is carried into the relay unit by the first transfer mechanism, if there is established a state where a second process object, which is to be carried from the second multi-chamber apparatus into the first multi-chamber apparatus next, can not be carried into the relay unit, the first process object is kept suspended in the relay unit until there is established a state where the second process object can be carried into the relay unit, and thereafter the second transfer mechanism carries the first process object out of the relay unit and carries the second process object into the relay unit instead.

In the present invention, when the transfer mechanism associated with one of the multi-chamber apparatuses delivers a process object to the relay unit, the transfer mechanism associated with the other multi-chamber apparatus does not receive that process object (i.e., first process object) immediately. Instead, if there exists at least one process object which is being processed (or which has been processed) by a process module located around the transfer mechanism associated with the other multi-chamber apparatus, the transfer mechanism stands by until the leading one (i.e., second process object) of said at least one process object can be transferred to the relay unit in such a manner that the leading process object and the process object being placed in the relay unit are interchanged. By prioritizing the transferring of the process object(s) to and from the process module(s) over the receipt of the first process object from the relay unit as mentioned above, total throughput of the system is improved.

In one preferred embodiment of the present invention, it is monitored whether or not any process object exists on any transfer path extending from the interface module through the process modules of the first group to the relay unit. If there exists no process object on the transfer path at a point of time when the second transfer mechanism transfers the first process object to the relay unit, the first transfer mechanism receives the first process object located in the relay unit substantially without waiting. In addition, it is monitored whether or not any process object exists on any transfer path extending from the relay unit through the process modules of the second group back to the relay unit. If there exists no process object on the transfer path at a point of time when the first transfer mechanism transfers the first process object to the relay unit, the second transfer mechanism receives the first process object located in the relay unit substantially without waiting. In this way, under the situation where interchanging of process objects at a process module should not be performed, the first process object may be removed from the relay unit immediately.

In one preferred embodiment, the first transfer mechanism serially transfers process objects according to the process-step order. At each process module, the first transfer mechanism carries a process object, which has been processed in that process module, out of that process module and carries another following process object, which is to be processed in that process module next, into that process module instead. With such a serial transfer method, the present invention achieves advantageous effects sufficiently.

In one preferred embodiment in connection with the serial transfer method, the first transfer mechanism has two transfer arms that are capable of moving into and out of each of the process modules of the first group; and at one access to each process module, the first transfer mechanism carries a process object, which has been processed in that process module, out of that process module by using one of the two transfer arm, and carries another following process object, which is to be processed in that process module next, into that process module instead by using the other transfer arm. In this case, at one access to the relay unit, the first transfer mechanism may receive a returning process object from the relay unit by the one of the transfer arms and delivers a forwarding process object to the relay unit instead. In addition, at one access to the interface module, the first transfer mechanism may carry an unprocessed object out of the interface module by the one of the transfer arms and carry a returning process object into the interface module by the other transfer arm. The first transfer module may transfer a returning process object, which is received from the relay unit, directly to the interface module.

In one preferred embodiment, the second transfer mechanism serially transfers process objects according to the process-step order. At each process module, the second transfer mechanism carries a process object, which has been processed in that process module, out of that process module and carries another following process object, which is to be processed in that process module next, into that process module instead. In this case, preferably, the second transfer mechanism has two transfer arms that are capable of moving into and out of each of the process modules of the second group; and at one access to each process module, the second transfer mechanism carries a process object, which has been processed in that process module, out of that process module by using one of the two transfer arm, and carries another following process object, which is to be processed in that process module next, into that process module instead by using the other transfer arm.

The present invention is preferably applicable to a vacuum processing system. In one preferred embodiment of the present invention, the first transfer mechanism and the second transfer mechanism are disposed within a first vacuum transfer chamber and a second vacuum transfer chamber, respectively; the relay unit is disposed adjacent to a connection between the first vacuum transfer chamber and the second vacuum transfer chamber; each of the process modules of the first group has a vacuum process chamber which is connected to the first vacuum transfer chamber via a gate valve; and each of the process modules of the second group has a vacuum process chamber which is connected to the second vacuum transfer chamber via a gate valve. The interface module is connected to the first vacuum transfer chamber via a gate valve, and has a loadlock chamber which is configured to be capable of selectively switching between an atmospheric-pressure state and a reduced pressure state to temporarily keep a process object to be transferred between an atmospheric-pressure space and a reduced-pressure space. The first transfer mechanism moves within in the first vacuum transfer chamber of a reduced pressure to access the vacuum chambers of the process modules of the first group, the relay unit and the loadlock chamber. On the contrary, the second transfer mechanism moves within the second vacuum transfer chamber of a reduced pressure to access the vacuum chambers of the process modules of the second group, the relay unit. The first transfer mechanism and the second transfer mechanism are capable of performing wafer transfer without being synchronized with each other.

In such a vacuum processing system of a two-cluster connecting type, in general, the first vacuum transfer chamber and the second vacuum transfer chamber is connected with each other via a gate valve. However, the present invention is applicable to a vacuum processing system in which two vacuum transfer chambers are always communicated with each other.

In one preferred embodiment, there are provided: a load port that supports a cassette, which is capable of containing a plurality of process objects, under an atmospheric pressure; an atmospheric transfer module, which is connected to or placed adjacent to the load port, and which is connected to the loadlock module via a door valve; and a third transfer mechanism disposed in the atmospheric transfer module to transfer process objects between a cassette placed on the load port and the loadlock module.

### BRIEF DESCRIPTION OF DRAWINGS

FIG. 1 is a schematic plan view showing a substrate processing system in one embodiment of the present invention.

FIG. 2 is a diagram for explaining pick-and-place operation of a transfer mechanism (transfer robot) shown in FIG. 1.

FIG. 3 is a diagram showing an early step of a transfer sequence in one embodiment of the present invention in the substrate processing system shown in FIG. 1.

FIG. 4 is a diagram showing a step of the transfer sequence following the step shown in FIG. 3.

FIG. 5 is a diagram showing a step of the transfer sequence following the step shown in FIG. 4.

FIG. 6 is a diagram showing a step of the transfer sequence following the step shown in FIG. 5.

FIG. 7 is a diagram showing a step of the transfer sequence following the step shown in FIG. 6.

FIG. 8 is a diagram showing a step of the transfer sequence following the step shown in FIG. 7.

FIG. 9 is a diagram showing a step of the transfer sequence following the step shown in FIG. 8.

FIG. 10 is a diagram showing a step of the transfer sequence following the step shown in FIG. 9.

FIG. 11 is a diagram showing a step of the transfer sequence following the step shown in FIG. 10.

FIG. 12 is a diagram showing a step of the transfer sequence following the step shown in FIG. 11.

FIG. 13 is a diagram showing a step of the transfer sequence following the step shown in FIG. 12.

FIG. 14 is a diagram showing a step of the transfer sequence following the step shown in FIG. 13.

FIG. 15 is a diagram showing a step of the transfer sequence following the step shown in FIG. 14.

FIG. 16 is a diagram showing a step of the transfer sequence following the step shown in FIG. 15.

FIG. 17 is a diagram showing one step of a transfer sequence in a comparative example.

FIG. 18 is a diagram showing a step of the transfer sequence following the step shown in FIG. 17 in the comparative example.

FIG. 19 is a diagram showing a step of the transfer sequence following the step shown in FIG. 18 in the comparative example.

FIG. 20 is a table showing cycle times of the whole substrate processing system and parts thereof, while comparing the transfer sequence according to the present invention and the transfer sequence in the comparative example.

FIG. 21 is a diagram showing one step of a transfer sequence in another embodiment of the present invention in the substrate processing system shown in FIG. 1.

FIG. 22 is a diagram showing a step of the transfer sequence following the step shown in FIG. 21.

FIG. 23 is a diagram showing a step of the transfer sequence following the step shown in FIG. 22.

FIG. 24 is a diagram showing one step of a transfer sequence in a comparative example.

FIG. 25 is a diagram showing a step of the transfer sequence following the step shown in FIG. 24 in the comparative example.

FIG. 26 is a table showing cycle times of the whole substrate processing system and parts thereof, while comparing the transfer sequence according to the present invention and the transfer sequence in the comparative example.

### BEST MODE FOR CARRYING OUT THE INVENTION

Preferred embodiments of the present invention will be described below with reference to the accompanying drawings.

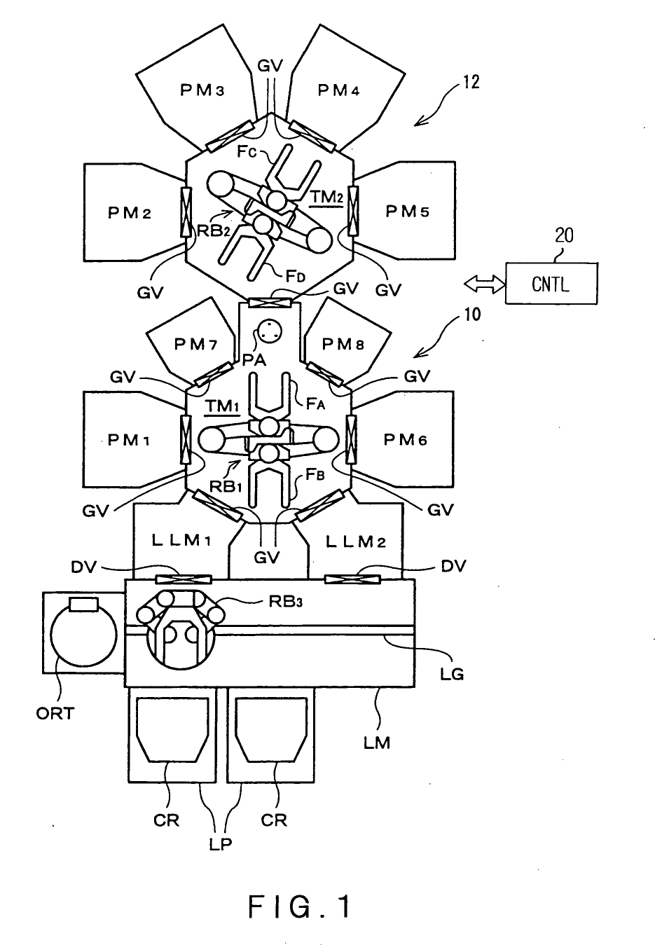

The configuration of a substrate processing system according to a first embodiment of the present invention is shown in FIG. 1. This substrate processing system includes two clusters 10 and 12 connected in series. A first cluster 10 is a multi-chamber apparatus which includes, a plurality of, for example, four process modules PM₁, PM₇, PM₈, and PM₆ and two loadlock modules LLM₁ and LLM₂ circularly arranged around a polygonal first transfer module TM₁ which constitutes a vacuum transfer chamber. In the first cluster 10, each module is provided with a vacuum chamber or a processing chamber which is capable of individually forming a reduced-pressure space with a desired degree of vacuum; and the first, central transfer module TM₁ is connected with each of the surrounding modules PM₁, PM₇, PM₈, PM₆, LLM₁, and LLM₂ through a gate valve GV.

On the other hand, a second cluster 12 is a multi-chamber apparatus which includes a plurality of, for example, four process modules PM₂, PM₃, PM₄, and PM₅ circularly arranged around a polygonal second transfer module TM₂ which constitutes a vacuum transfer chamber. Also in the second cluster 12, each module is provided with a vacuum chamber or a processing chamber which is capable of individually forming a reduced-pressure space with a desired degree of vacuum; and the second, central transfer module TM₂ at the central part of the second cluster 12 is connected with each of the surrounding modules PM₂, PM₃, PM₄, and PM₅ through a gate valve GV.

The first transfer module TM₁ of the first cluster 10 and the second transfer module TM₂ of the second cluster 12 are mutually connected through a gate valve GV. A pass unit PA is provided as a relay unit at a protruded portion of the first transfer module TM₁ adjacent to the gate valve GV. The pass unit PA has a plurality of support pins is capable of horizontally supporting one process object, for example, a semiconductor wafer (hereinafter referred to simply as “wafer”). The support pins may be vertically movable in order to support wafer transfer.

A first vacuum transfer robot RB₁ having a pair of rotatable/expandable transfer arms F_{A} and F_{B} is provided in the chamber of the first transfer module TM₁. Each of the transfer arms F_{A} and F_{B} of the first vacuum transfer robot RB₁ can hold a single wafer in its fork-shaped end effecter. The first vacuum transfer robot RB₁ can perform carrying in-and-out (loading and unloading) of a wafer by inserting the transfer arm F_{A} or F_{B} into each of the surrounding modules PM₁, PM₇, PM₈, PM₆, LLM₁, and LLM₂, and then retracting it therefrom through an open gate valve GV. Likewise, the first vacuum transfer robot RB₁ can also perform wafer transfer to/from the pass unit PA. The transfer arms F_{A} and F_{B}, mounted on the robot body back to back, integrally rotate. While one transfer arm stops at its home position, i.e., return position, the other transfer arm expands or retracts, that is, moves back or forth within a range between its home position and its forward position on the forward side.

Likewise, the second vacuum transfer robot RB₂ having a pair of rotatable/expandable transfer arms F_{C} and F_{D} is provided in the chamber of the second transfer module TM₂. Each of the transfer arms F_{C} and F_{D} of the second transfer robot RB₂ can hold a single wafer in its fork-shaped end effecter. The second vacuum transfer robot RB₂ can perform carrying in-and-out (loading and unloading) a wafer by inserting the transfer arm F_{C} or F_{D} into each of the surrounding modules PM₂, PM₃, PM₄, and PM₅, and then retracting it therefrom through an open gate valve GV. Likewise, the second vacuum transfer robot RB₂ can also perform wafer transfer to/from the pass unit PA through an open gate valve GV. The transfer arms F_{C} and F_{D}, mounted on the robot body back to back, integrally rotate. While one transfer arm stops at its home position, i.e., return position, the other transfer arm expands or retracts, that is, moves back and forth within a range between its home position and its forward position on the forward side.

The process modules PM₁ to PM₈ perform predetermined single-wafer processing, for example, a film-forming process such as CVD or sputtering, a thermal process, a dry etching process, etc. using predetermined utility energy (processing gas, electric power, etc.) within each chamber. Further, the loadlock modules LLM₁ and LLM₂ may also be provided with a heating unit or a cooling unit as required.

Each of the loadlock modules LLM₁ and LLM₂ is connected with a loader module LM, whose interior is always kept at the atmospheric pressure, on the side opposite to the side of the transfer modules TM, through a door valve DV. Further, adjacent to the loader module LM, load ports LP and an orientation flat aligning mechanism ORT are provided. The load ports LP are used to load and unload wafer cassettes CR to and from an external transfer vehicle. The orientation flat aligning mechanism ORT is used to align an orientation flat or a notch of a wafer W with a predetermined position or orientation.

An atmospheric transfer robot RB₃ provided in the loader module LM has a pair of (upper and lower) expandable transfer arms. The atmospheric transfer robot RB₃ can horizontally move on a linear guide (linear slider) LG as well as vertically move and rotate. The atmospheric transfer robot RB₃ moves between the load ports LP, the orientation flat aligning mechanism ORT, and the loadlock modules LLM₁ and LLM₂ to transfer wafers one by one or in units of two. The linear guide LG is composed of a permanent magnet, an excitation coil for drive, a scale head, etc., to perform linear drive control of the atmospheric transfer robot RB₃ in response to a command from a host controller.

The following explains a basic wafer transfer sequence for making a wafer in a wafer cassette CR loaded into a load port LP be subjected to a series of processing within the substrate processing system. Single-wafer processes of the first and second process steps are respectively performed by the process modules PM₇ and PM₁ of the first cluster 10 in that order; subsequently, single-wafer processes of the third and fourth process steps are respectively performed by the process modules PM₄ and PM₃ of the second cluster 12 in that order. In this case, the single-wafer processes of the first and second process steps are first phase processing, and the single-wafer processes of the third and fourth process steps are second phase processing. Transfer sequence within the substrate processing system is performed by exchanging predetermined control signals between the host controller which performs integrated control of the entire system and each local controller which controls operation of each module. Alternatively, a single controller may directly control the operation of each module. A controller (CNTL) denoted by a reference numeral 20 in FIG. 1 may be of any one of the above-mentioned types.

The atmospheric transfer robot RB₃ of the loader module LM picks up a wafer Wᵢ from a wafer cassette CR on a load port LP, and transfers the wafer Wᵢ to the orientation flat aligning mechanism ORT. Orientation flat aligning is performed by the orientation flat aligning mechanism ORT. After the orientation flat aligning is completed, the atmospheric transfer robot RB₃ transports the wafer Wᵢ to one of the loadlock modules LLM₁ and LLM₂ (here, LLM₁). The loadlock module LLM₁ receives the wafer Wᵢ in the atmospheric pressure state, performs vacuuming of the chamber, and transfers the wafer Wᵢ to the first vacuum transfer robot RB1 of the first transfer module TM₁ in a reduced pressure state.

The first vacuum transfer robot RB₁ picks up the wafer Wᵢ from the loadlock module LLM₁ and then loads it into the first process module PM₇ by use of one of the transfer arms F_{A} and F_{B}. The process module PM₇ performs a single-wafer process of the first process step under predetermined process conditions (gas, pressure, electric power, temperature, time, etc.) based on a preset recipe. After the single-wafer process of the first process step is completed, the first vacuum transfer robot RB₁ unloads the wafer Wᵢ from the process module PM₇ and then loads it into the second process module PM₁. The process module PM₁ performs a single-wafer process of the second process step under predetermined process conditions based on a preset recipe. When the single-wafer process of the second process step is completed, the first vacuum transfer robot RB₁ unloads the wafer Wᵢ from the process module PM₁ and then transfers it to the pass unit PA. The pass unit PA horizontally supports the received wafer Wᵢ to keep it.

The second vacuum transfer robot RB₂ of the second transfer module TM₂ picks up the wafer Wᵢ from the pass unit PA and then loads it into the third process module PM₄. The process module PM₄ performs a single-wafer process of the third process step under predetermined process conditions based on a preset recipe. After the single-wafer process of the third process step is completed, the second vacuum transfer robot RB₂ unloads the wafer Wᵢ from the process module PM₄ and then loads it into the fourth process module PM₃. The process module PM₃ performs a single-wafer process of the fourth process step under predetermined process conditions based on a preset recipe. When the single-wafer process of the fourth process step is completed, the second vacuum transfer robot RB₂ unloads the processed wafer Wᵢ from the process module PM₃ and then returns it to the pass unit PA. The pass unit PA horizontally supports the received (processed) wafer, i.e., the returning wafer Wᵢ to keep it.

Thereafter, the first vacuum transfer robot RB₁ of the first transfer module TM₁ picks up the returning wafer Wᵢ returned to the pass unit PA and then returns it to one of the loadlock modules LLM₁ and LLM₂.

In this way, when the processed wafer Wᵢ that has been subjected to consecutive processes by a plurality of process modules PM₇, PM₁, PM₄, and PM₃ in the substrate processing system is loaded into one of the loadlock modules (here, LLM₂), the chamber of the loadlock module LLM₂ is changed from a reduced pressure state to the atmospheric pressure state. Thereafter, the atmospheric transfer robot RB₃ of the loader module LM picks up the wafer Wᵢ from the loadlock module LLM₂ in the atmospheric pressure state and then returns it to the relevant wafer cassette CR. It is also possible to subject the wafer Wᵢ suspended in the loadlock modules LLM₁ and LLM₂ to heating or cooling process under a desired atmosphere.

As mentioned above, the substrate processing system can transfer wafers one by one to a plurality of process modules according to the order of the process steps to continuously perform a series of processes within two clusters 10 and 12 connected in series. For example, the substrate processing system makes it possible to laminate a plurality of types of thin films on a wafer by performing vacuum processes under different process conditions in each process module by use of a plurality of process modules in relation to two clusters.

Especially, in order to maximize the throughput capacity of the substrate processing system, with serial transfer for transferring wafers W one by one to a plurality of process modules (PM₇, PM₁, PM₄, and PM₃ in the above example) according to the order of the process steps over the first cluster 10 and the second cluster 12, it is most suitable to employ an interchange transfer method. With the interchange transfer method, a wafer Wᵢ that has been processed in a process module PM is unloaded therefrom and, in turn, a next wafer Wᵢ₊₁, immediately after being unloaded from a process module for the previous process step, is loaded into the process module PM instead.

However, a forwarding wafer W→ to be moved from the first cluster 10 to the second cluster 12, and a returning wafer W← to be moved vice versa are suspended in a common relay unit PA at different timings. Therefore, if a transfer sequence for the forwarding wafer W→ and a transfer sequence for the returning wafer W← collide with or compete against each other in the relay unit PA, the throughput may be degraded. In such a case, the degradation of the throughput is minimized by using a transfer procedure according to the present invention to be mentioned later.

In the substrate processing system, the first vacuum transfer robot RB₁ of the first transfer module TM₁ is provided with the pair of transfer arms F_{A} and F_{B} as mentioned above, allowing a pick & place operation in which a wafer immediately after being processed in a module is interchanged with a wafer to be processed next in that module through a series of access operations, for each of the process modules PM₁, PM₇, PM₈, and PM₆ surrounding the first vacuum transfer robot RB₁.

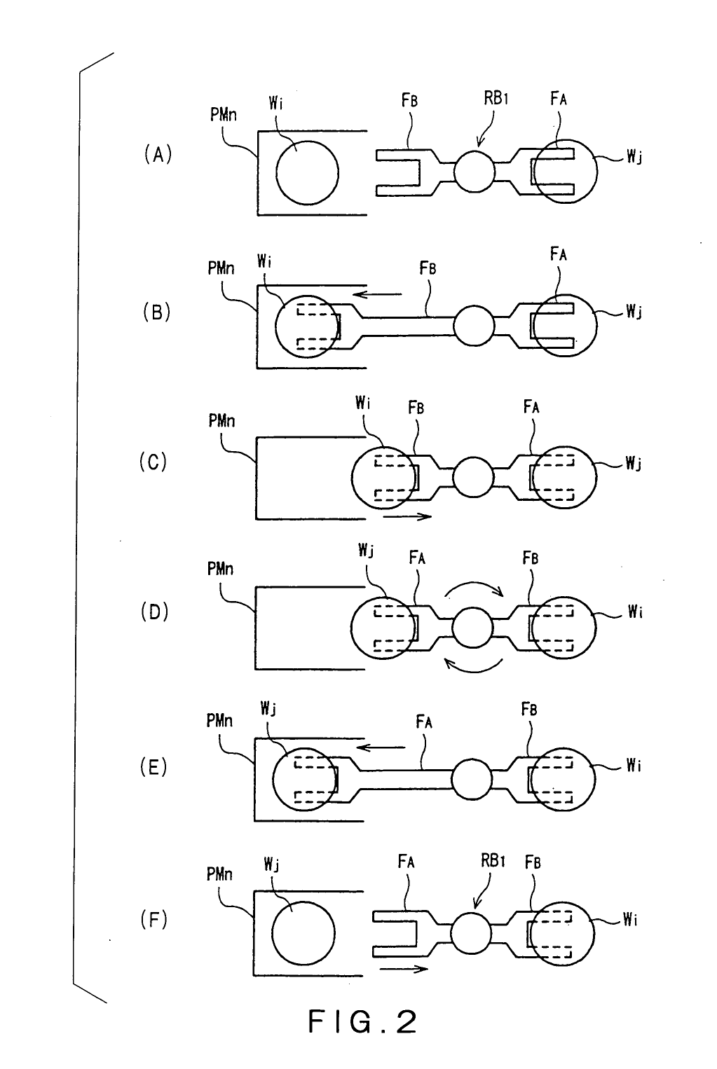

The pick & place operation will be explained below with reference to FIG. 2. As shown in (A) of FIG. 2, the first vacuum transfer robot RB₁ holds an unprocessed wafer Wⱼ (before processed) to be loaded into the process module PMₙ by use of one transfer arm, for example, F_{A}, and sets the other (empty) transfer arm, F_{B}, not having a wafer, so as to oppose the process module PMₙ. Then, as shown in (B) and (C) of FIG. 2, the first vacuum transfer robot RB₁ inserts the empty transfer arm F_{B} into the chamber of the process module PMₙ and then picks up the processed Wᵢ therefrom (pick operation). Then, as shown in (D) of FIG. 2, the first vacuum transfer robot RB₁ rotates the transfer arms F_{A} and F_{B} by 180 degrees (inversion) to set the transfer arm F_{A} holding the unprocessed wafer Wⱼ so as to oppose the process module PMₙ. Then, as shown in (E) and (F) of FIG. 2, the first vacuum transfer robot RB₁ inserts the transfer arm F_{A} into the chamber of the process module PMₙ, transfers the wafer Wⱼ to wafer support means, such as a mount table or a support pin provided in the chamber, and retracts the emptied transfer arm F_{A} (place operation). During the pick & place operation, the gate valve GV (refer to FIG. 1) provided in the wafer entrance of the relevant process module PMₙ remains open.

In this way, through a series of access operation for each process module PMₙ (this means that, during a series of access operation to one certain module, access operation to other modules is not performed), the first vacuum transfer robot RB₁ of the transfer module TM₁ can interchange a wafer Wᵢ that has been processed in that module and a wafer Wⱼ to be processed next in that module through the above-mentioned pick & place operation. Further, the first vacuum transfer robot RB₁ can interchange or transfer an unprocessed wafer and a processed wafer through the same pick & place operation as above also for each of the loadlock modules LLM₁ and LLM₂.

Further, the first vacuum transfer robot RB₁ can interchange a forwarding wafer W→ and a returning wafer W← through the same pick & place operation as above also for the pass unit PA. Specifically, the first vacuum transfer robot RB₁ performs the steps of: picking up the returning wafer W← from the pass unit PA by use of the empty transfer arm F_{B} (pick operation); rotating the transfer arms F_{A} and F_{B} by 180 degrees (inversion) to set the transfer arm F_{A} holding the forwarding wafer W→ so as to oppose the pass unit PA; extending the transfer arm F_{A} to transfer the forwarding wafer W→ to the support pin of the pass unit PA; and retracting the emptied transfer arm F_{A} (place operation).

Further, when the first vacuum transfer robot RB₁ performs a series of above-mentioned access operation, it is also possible to perform the place operation immediately after the pick operation or in a certain period of time after the pick operation. Further, it is also possible to perform only the pick operation for unloading (receiving) a wafer Wᵢ (W←) or only the place operation for loading (placing) a wafer Wⱼ (W→).

Likewise, the second vacuum transfer robot RB₂ of the second transfer module TM₂ is provided with a pair of transfer arms F_{C} and F_{D}, allowing the above-mentioned pick & place operation in which a wafer Wᵢ immediately after being processed in a process module can be interchanged with a wafer Wⱼ to be processed next in that process module, for each of the process modules PM₂, PM₃, PM₄, and PM₅ surrounding the second vacuum transfer robot. Further, the second vacuum transfer robot RB₂ can also interchange a forwarding wafer W→ and a returning wafer W← through the same pick & place operation as above also for the pass unit PA. Further, similarly, the second vacuum transfer robot RB₂ can also perform the place operation immediately after the pick operation or in a certain period of time after the pick operation. Further, the second vacuum transfer robot RB₂ can also perform only the pick-up operation for unloading (receiving) a wafer Wᵢ (W→) or only the place operation for loading (placing) a wafer Wⱼ (W←).

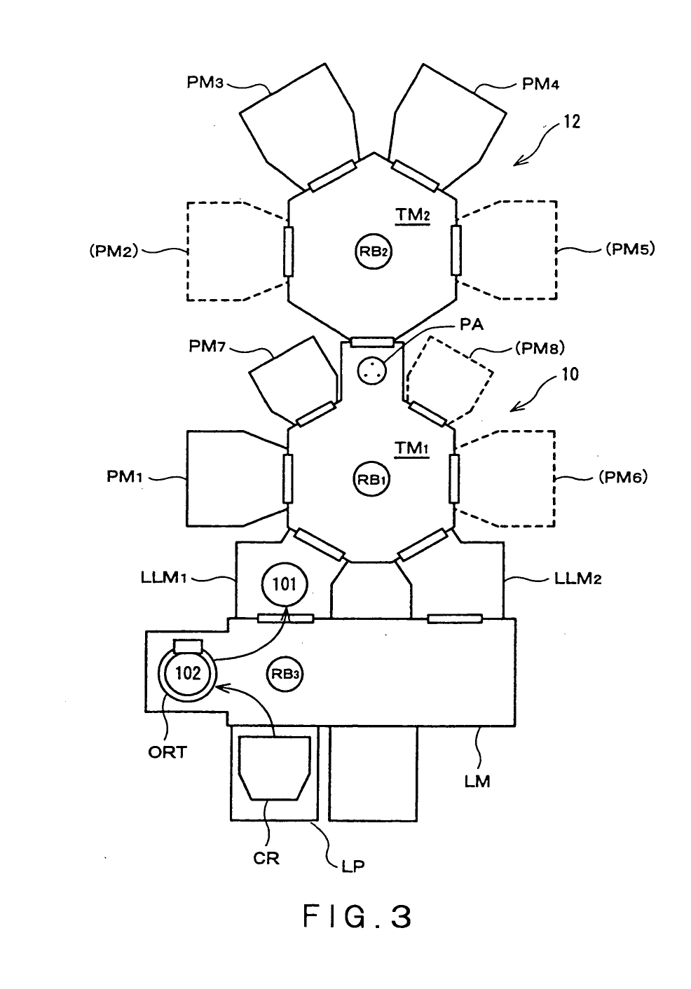

With reference to FIGS. 3 to 20, the following explains an embodiment of a transfer sequence for transferring wafers W one by one to a plurality of process modules in a cluster tool, based on a serial transfer method, in order to continuously perform a series of processes to a group of wafers loaded in load ports LP on a cassette basis in the substrate processing system shown in FIG. 1. In the serial transfer method, it is desirable to set all the process time in each process module to the same value.

The present embodiment sequentially forms TaN/Ta laminated films which constitute a barrier layer and a Cu seed layer on a base layer (Cu), in the copper wiring process employing a copper plating film. Specifically, for each wafer W, the present embodiment performs the steps of: removing gas absorbed to the surface of the lower layer (Cu) by a degas process by use of the process module PM₇ in the first cluster 10; cleaning the surface of the base layer (Cu) through etching by the process module PM₁ in the first cluster 10; forming TaN/Ta laminated films through the iPVD (ionized Physical Vapor Deposition) method by use of the process module PM₄ in the second cluster 12; and forming a Cu seed layer using the iPVD method by means of the process module PM₃ in the second cluster 12. Then, the present embodiment cools the processed wafer by use of the loadlock modules LLM₁ and LLM₂. Here, the remaining process modules PM₈, PM₆, PM₂, and PM₅ do not operate.

As shown in FIG. 3, out of a plurality of, for example 25, wafers (W101 to W125) (here, one production lot includes 25 wafers) stored in a wafer cassette CR on a load port LP, a first wafer W101 is transferred to one of the loadlock modules LLM₁ and LLM₂ (here, first loadlock module LLM₁) through the orientation flat aligning mechanism ORT. While the loadlock module LLM₁ into which the wafer W101 was loaded is performing vacuuming of the chamber, the second wafer W102 is subjected to orientation flat aligning by the orientation flat aligning mechanism ORT. As mentioned above, transferring of the wafers between the load ports LP, the orientation flat aligning mechanism ORT, and the loadlock modules LLM₁ and LLM₂ are all performed by the atmospheric transfer robot RB₃ of the loader module LM.

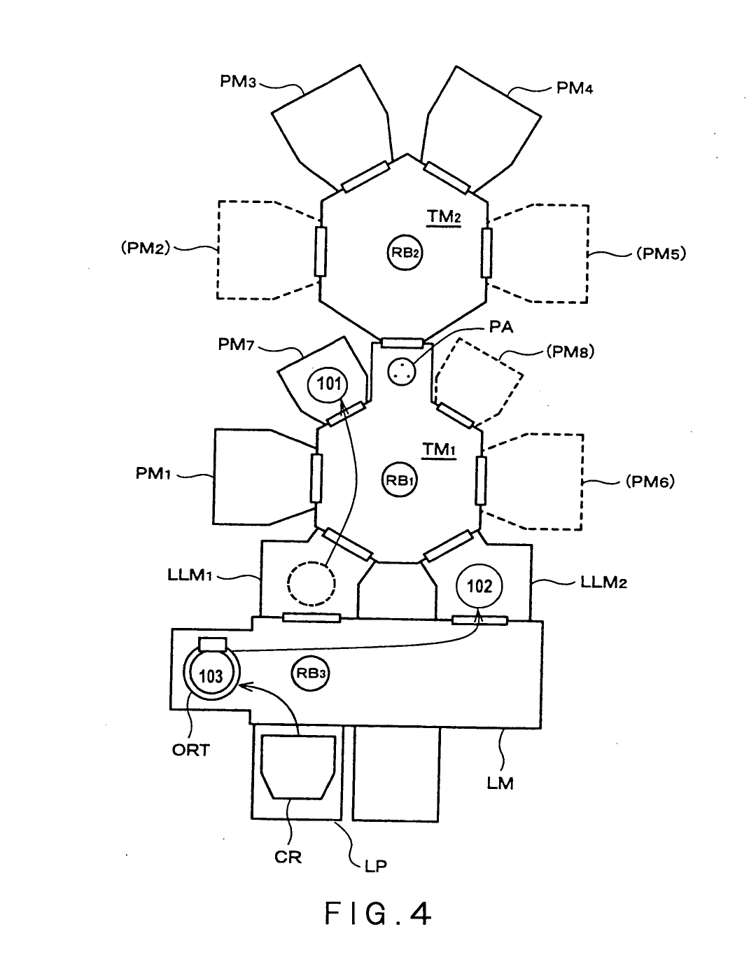

Then, when the loadlock module LLM₁ completes vacuuming, the wafer W101 is transferred from the loadlock module LLM₁ to the process module PM₇ for the first process step through the first transfer module TM₁, as shown in FIG. 4. As mentioned above, transferring of wafers in the first cluster 10 are all performed by the first vacuum transfer robot RB₁. On the other hand, in the atmospheric transfer system, the wafer W102 is moved from the orientation flat aligning mechanism ORT to the other (second) loadlock module LLM₂, and a third wafer W103 is transferred from a cassette CR to the orientation flat aligning mechanism ORT.

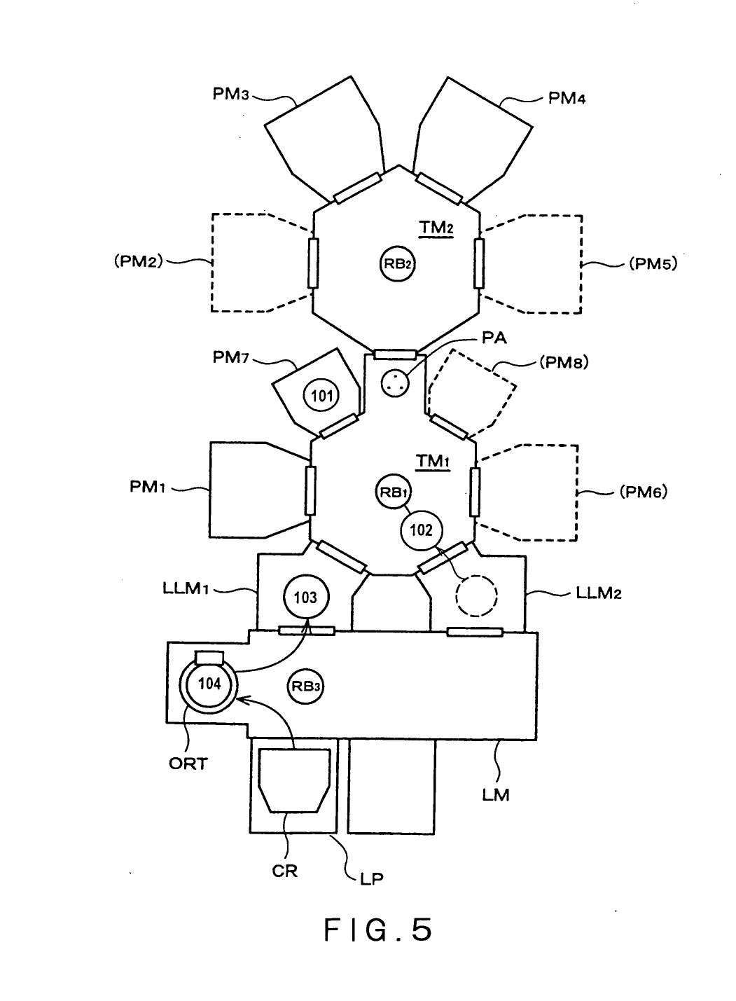

The process module PM₇ performs the degas process for the loaded wafer W101 under predetermined process conditions based on a preset recipe. Meanwhile, as shown in FIG. 5, the loadlock module LLM₂ completes vacuuming, and the first vacuum transfer robot RB₁ picks up the wafer W102 from the loadlock module LLM₂. Further, in the atmospheric transfer system, the wafer W103 is moved from the orientation flat aligning mechanism ORT to the first loadlock module LLM₁ and, in turn, a fourth wafer W104 is transferred from a cassette CR to the orientation flat aligning mechanism ORT.

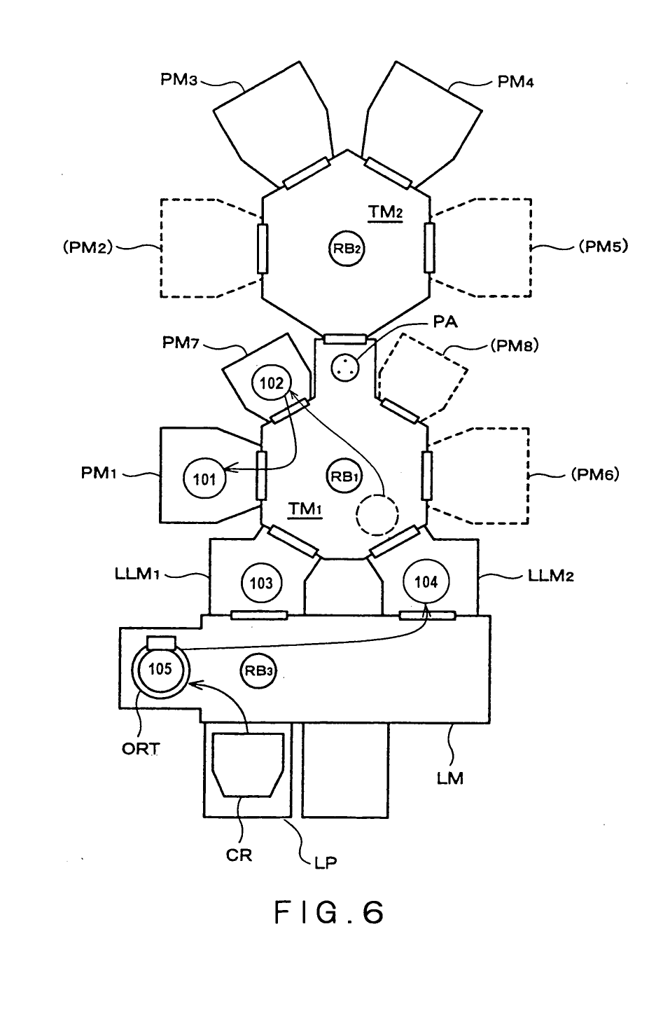

When the process module PM₇ completes the degas process for the wafer W101, the wafer W101 is moved from the process module PM₇ to the process module PM₁ for the second process step in the same, first cluster 10 and, in turn, the wafer W102 that has been suspended in the first transfer module TM₁ is loaded into the process module PM₇, as shown in FIG. 6. In this case, through the above-mentioned pick & place operation, the wafer W101 is unloaded from the process module PM₇ and, in turn, the wafer W102 is loaded into the process module PM₇ instead.

When the wafer W102 is loaded, the process module PM₇ starts performing a degas process under the same process conditions as those for the wafer W101. After some delay, the process module PM₁ starts a base layer surface etching process, or a cleaning process, for the loaded wafer W101 under predetermined process conditions based on a preset recipe. On the other hand, the loadlock module LLM₁ containing the wafer W103 performs vacuuming in the chamber. Further, in the atmospheric transfer system, the wafer W104 is moved to the loadlock module LLM₂, and a fifth wafer W105 is transferred from a cassette CR to the orientation flat aligning mechanism ORT.

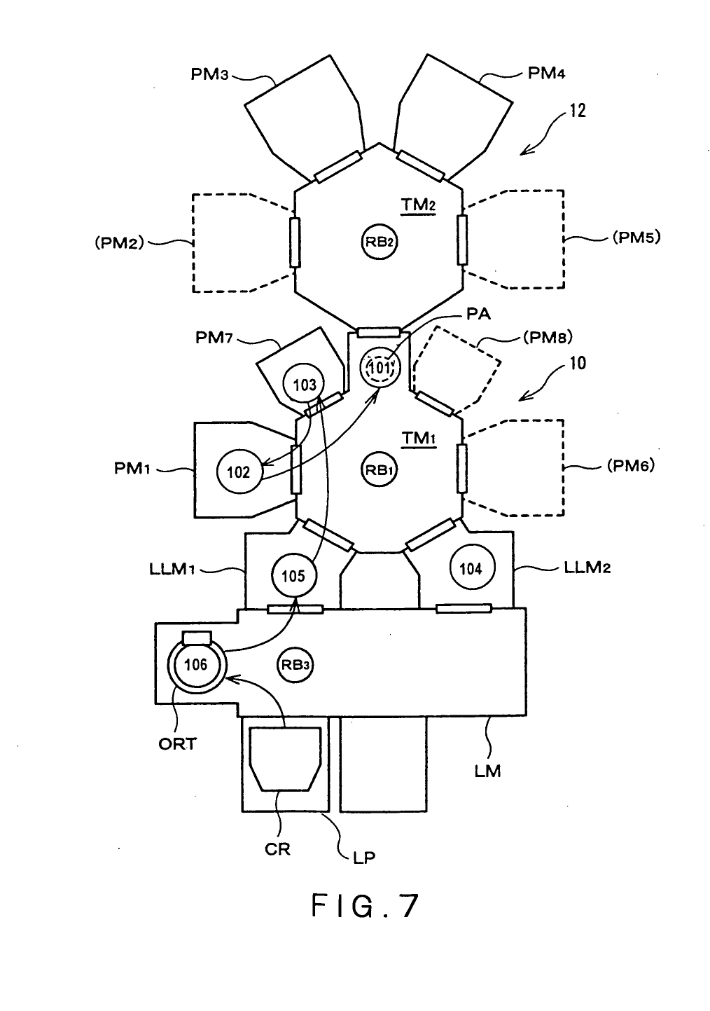

Thereafter, when the process module PM₇ completes the degas process and the process module PM₁ completes the cleaning process, the wafer W101 is moved from the process module PM₁ to the pass unit PA, the wafer W102 is moved from the process module PM₇ to the process module PM₁, and the wafer W103 is moved from the loadlock module LLM₁ to the process module PM₇, as shown in FIG. 7.

The transfer procedure in this case is as follows: First, when the loadlock module LLM₁ completes vacuuming, the wafer W103 is picked up into the first transfer module TM₁. Then, when the process module PM₇ completes the degas process, the wafer W102 is unloaded from the process module PM₇ and, in turn, the wafer W103 that has been suspended in the first transfer module TM₁ is loaded into the process module PM₇ instead, through the pick & place operation. Subsequently, when the process module PM₁ completes the cleaning process, the wafer W101 is unloaded from the process module PM₁ and, in turn, the wafer W102 that has been unloaded from the process module PM₇ is loaded into the process module PM₁ instead, through the pick & place operation. Then, the wafer W101 unloaded from the process module PM₁ is transferred to the pass unit PA.

Further, after the wafer W103 is unloaded from the loadlock module LLM₁ into the first transfer module TM₁, the chamber of the loadlock module LLM₁ is changed to the atmospheric pressure, and the wafer W105 that completed the orientation flat aligning is loaded into the loadlock module LLM₁. A sixth wafer W106 is transferred from a cassette CR to the orientation flat aligning mechanism ORT.

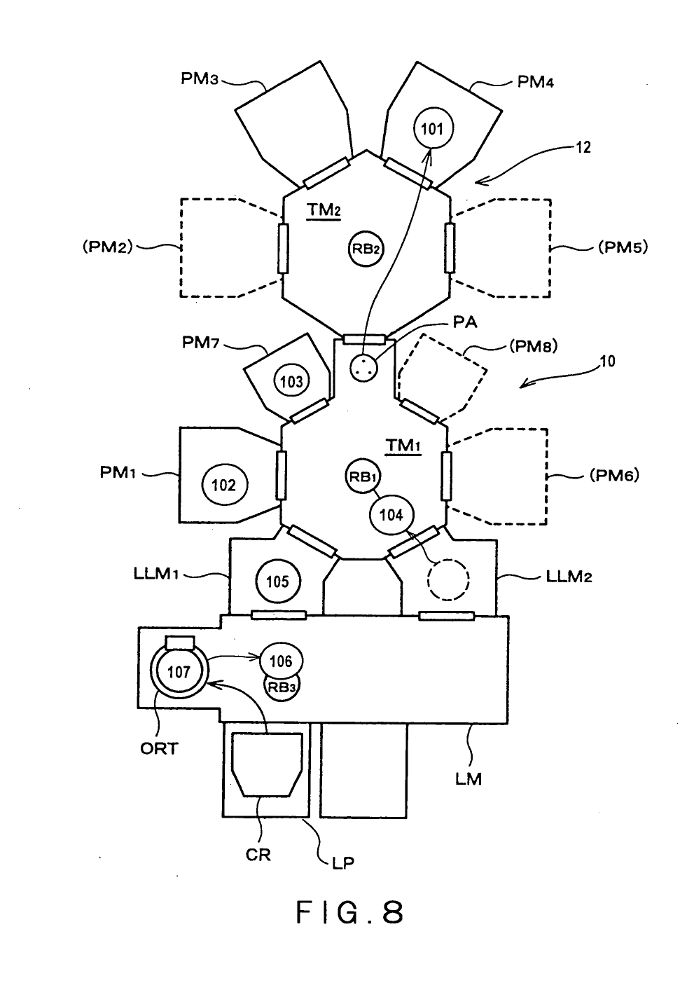

Thereafter, as shown in FIG. 8, the second vacuum transfer robot RB₂ of the second cluster 12 picks up the wafer W101 from the pass unit PA, and then loads it into the process module PM₄ for the third process step. The process module PM₄ starts the TaN/Ta laminated films forming process for the loaded wafer W101 by use of the iPVD method under predetermined process conditions based on a preset recipe. On the other hand, in the first cluster 10, when the loadlock module LLM₂ completes vacuuming, the wafer W104 is unloaded from the loadlock module LLM₂ to the first transfer module TM₁. Further, in the atmospheric transfer system, the wafer W106 is received from the orientation flat aligning mechanism ORT by the atmospheric transfer robot RB₃ and, in turn, a seventh wafer W107 is transferred from a cassette CR to the orientation flat aligning mechanism ORT.

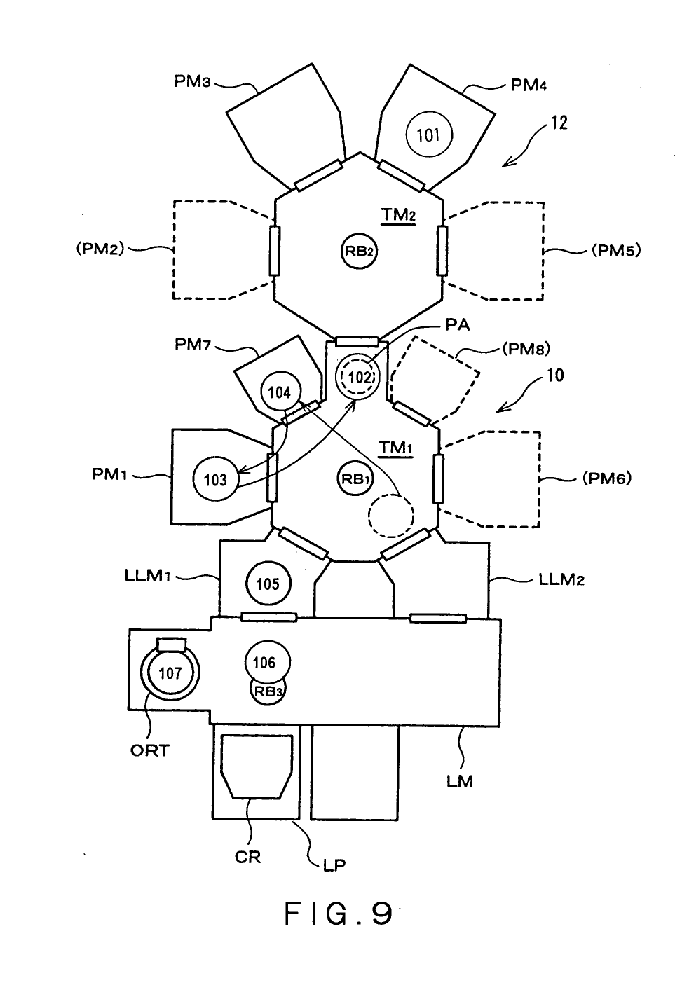

Thereafter, when the process module PM₇ completes the degas process and the process module PM₁ completes the cleaning process, the wafer W102 is transferred from the process module PM₁ to the pass unit PA, the wafer W103 is transferred from the process module PM₇ to the process module PM₁, and the wafer W104 is loaded into the process module PM₇, as shown in FIG. 9. Transferring of wafers W102, W103, and W104 in this scene is performed with exactly the same procedures as those of above-mentioned transferring of the wafers W101, 102, and 103. The process modules PM₇ and PM₁ perform the degas process and the cleaning process for the newly loaded wafers W104 and W103, respectively, under the same process conditions as above.

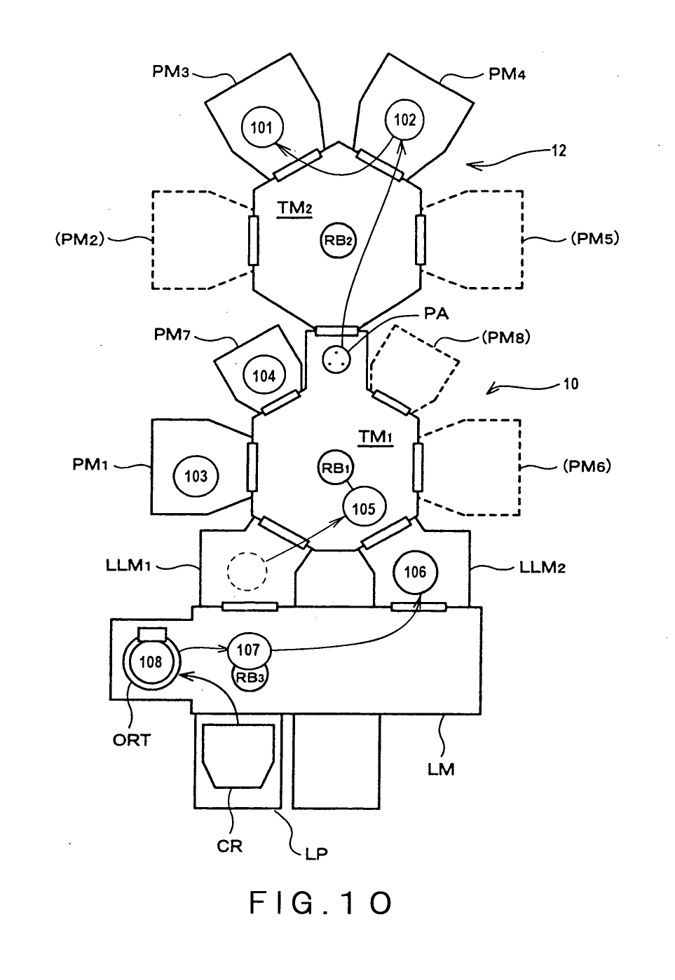

In the second cluster 12, the second vacuum transfer robot RB₂ unloads the wafer W101 from the process module PM₄ that completed the TaN/Ta laminated film forming process, and then loads it into the process module PM₃ for the fourth process step, as shown in FIG. 10. The process module PM₃ starts Cu seed layer forming process for the loaded wafer W101 using the iPVD method under predetermined process conditions based on a preset recipe. Then, the second vacuum transfer robot RB₂ loads the wafer W102, received from the pass unit PA, into the emptied process module PM₄. The process module PM₄ performs the TaN/Ta laminated film forming process for the newly loaded wafer W102 under the same process conditions as those for the wafer W101.

In this case, the second vacuum transfer robot RB₂ can employ a transfer procedure that firstly receives the wafer W102 from the pass unit PA; then performs the pick & place operation for the process module PM₄ to interchange the wafers W101 and W102; and immediately thereafter, loads the wafer W101 into the process module PM₃ through a sole place operation. Alternatively, since the wafer W101 is the leading wafer of the production lot (that is, there is no wafer preceding it), the second vacuum transfer robot RB₂ may firstly unload the wafer W101 from the process module PM₄ through a sole pick operation; immediately thereafter, load it into the process module PM₃ through a sole place operation; and thereafter receive the wafer W102 from the pass unit PA through a sole pick operation and loads it into the process module PM₄ through a sole place operation.

On the other hand, in the first cluster 10, the first vacuum transfer robot RB₁ carries the wafer W105 out of the loadlock module LLM₁ that has completed vacuuming, as shown in FIG. 10. Further, in the atmospheric transfer system, the wafer W107 is received from the orientation flat aligning mechanism ORT by the atmospheric transfer robot RB₃ and, in turn, an eighth wafer W108 is transferred from a cassette CR to the orientation flat aligning mechanism ORT.

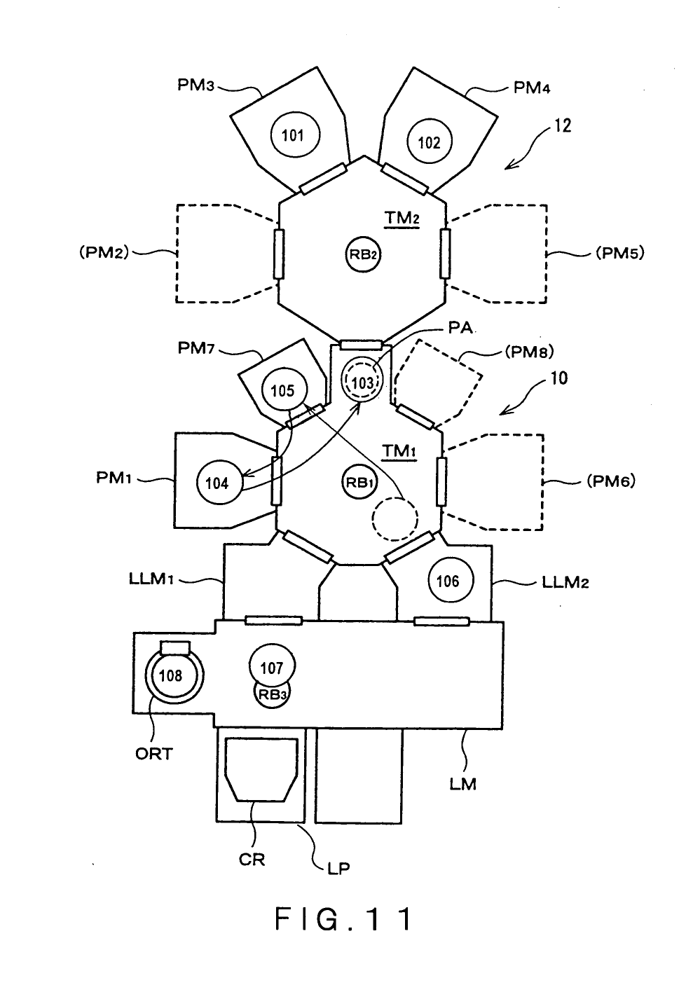

Thereafter, when the process module PM₇ completes the degas process and the process module PM₁ completes the cleaning process in the first cluster 10, the wafer W103 is transferred from the process module PM₁ to the pass unit PA, the wafer W104 is transferred from the process module PM₇ to the process module PM₁, and the wafer W105 is loaded into the process module PM₇, as shown in FIG. 11. Transferring of the wafers W103, 104, and 105 in this case is performed with exactly the same procedures as those of above-mentioned serial transferring of the wafers W102, 103, and 104. Each of the process modules PM₇ and PM₁ performs the degas process and the cleaning process for the newly loaded wafers W105 and W104, respectively, under the same process conditions as above.

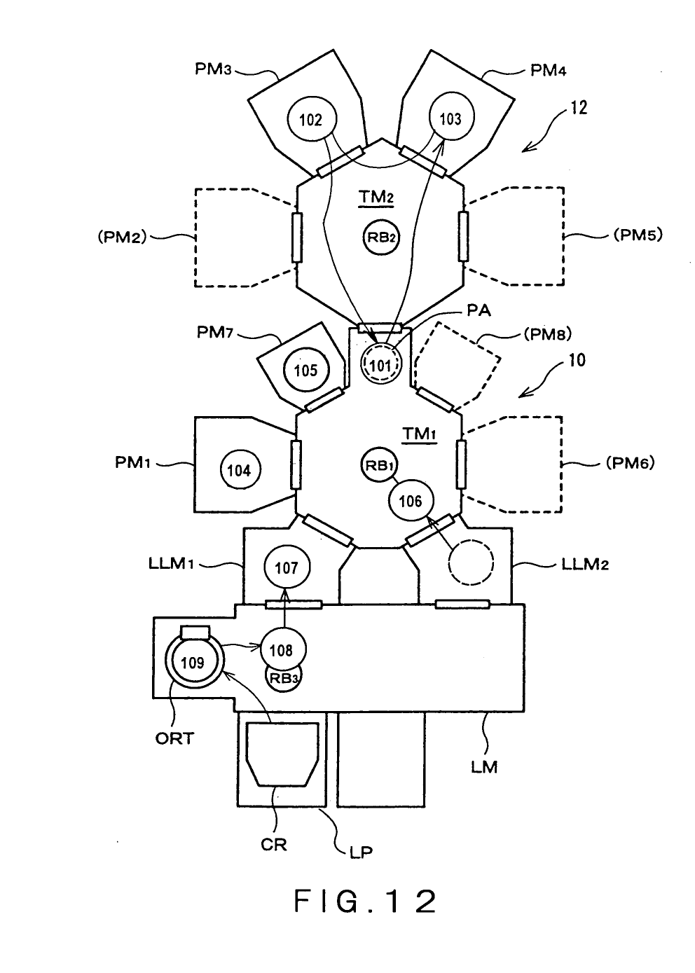

Thereafter, in the second cluster 12, the second vacuum transfer robot RB₂ unloads the wafer W101 from the process module PM₃ that has completed Cu seed layer forming process and returns it back to the pass unit PA; unloads the wafer W102 from the process module PM₄ that has completed the Ti/TiN laminated films forming process and transfers it to the process module PM₃; and loads the forwarding wafer W103, which has been transferred from the first cluster 10 side to the pass unit PA, into the process module PM₄, as shown in FIG. 12. The process modules PM₄ and PM₃ performs the TaN/Ta laminated films forming process and the Cu seed layer forming process for the newly loaded wafers W103 and W102, respectively, under the same process conditions as previously described

In this case, the second vacuum transfer robot RB₂ can employ a transfer procedure that firstly receives the wafer W103 from the pass unit PA; performs the pick & place operation for the process module PM₄ to interchange the wafers W102 and W103; immediately thereafter, performs the pick & place operation for the process module PM₃ to interchange the wafers W101 and W102; and finally transfers the wafer W101, picked up from the process module PM₃, to the pass unit PA. Also in this case, however, the wafer W101 is the leading wafer of the production lot (there is no wafer preceding it) and therefore it is possible to employ the following exceptional procedure. That is, the exceptional procedure firstly unloads the wafer W101 from the process module PM₃ through a sole pick operation; performs the pick & place operation for the pass unit PA to interchange the wafers W101 and W103 immediately after the forwarding wafer W103 arrives at the pass unit PA; performs the pick & place operation for the process module PM₄ to interchange the wafers W102 and W103; and finally loads the wafer W102, unloaded from the process module PM₄, into the process module PM₃ through a sole place operation. This transfer procedure can return the leading wafer W101, having been processed, to the pass unit PA at an earlier timing.

On the other hand, in the first cluster 10, the wafer W106 is unloaded from the loadlock module LLM₂ that has completed vacuuming before the returning wafer W101 is transferred from the second cluster 12 to the pass unit PA, as shown in FIG. 12. Further, in the atmospheric transfer system, the wafer W107 is loaded into the loadlock module LLM₁, the wafer W108 is received by the atmospheric transfer robot RB₃ from the orientation flat aligning mechanism ORT and, in turn, a ninth wafer W109 is transferred from a cassette CR to the orientation flat aligning mechanism ORT.

When the returning wafer W101 is transferred to the pass unit PA from the second cluster 12 in the foregoing manner, in the first cluster 10, the first vacuum transfer robot RB₁ holds the unprocessed wafer W106 in one transfer arm, the process modules PM₇ and PM₁ perform the degas process and the cleaning process for wafers W105 and W104, respectively, and one loadlock module LLM₁ is performing vacuuming while holding therein the unprocessed wafer W107 as shown in FIG. 12. At this timing, the other transfer arm of the first vacuum transfer robot RB₁ is emptied and therefore it is possible to pick up the returning wafer W101 having been transferred from the second cluster 12 to the pass unit PA using the emptied transfer arm.

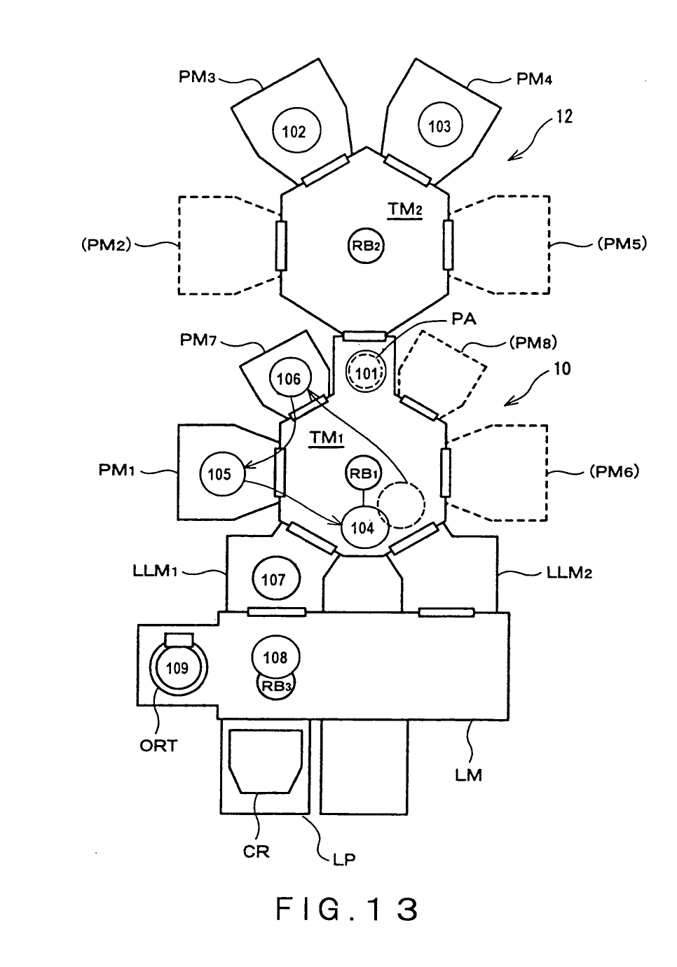

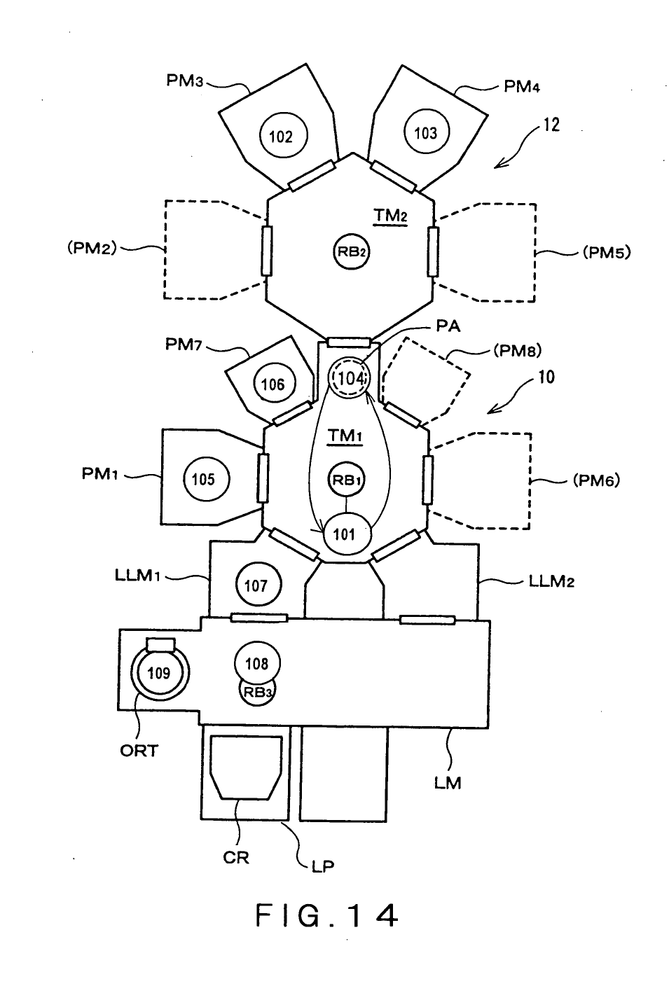

However, in accordance with the present invention, the first vacuum transfer robot RB₁ preferentially performs serial transfer in the first cluster 10 while suspending the returning wafer W101 in the pass unit PA. Specifically, as shown in FIG. 13, the first vacuum transfer robot RM₁ performs the pick & place operation for the process module PM₇ that has completed the degas process to interchange wafers W105 and W106, and then performs the pick & place operation for the process module PM₁ to interchange wafers W104 and W105. Then, while holding the wafer W104, unloaded from the process module PM₁, with one transfer arm, the first vacuum transfer robot RB₁ sets the other (empty) transfer arm so as to oppose the returning wafer W101 that has been suspended in the pass unit PA. Then, as shown in FIG. 14, the first vacuum transfer robot RM₁ picks up the returning wafer W101 from the pass unit PA and, in turn, transfers the forwarding wafer W104 instead, through the pick & place operation.

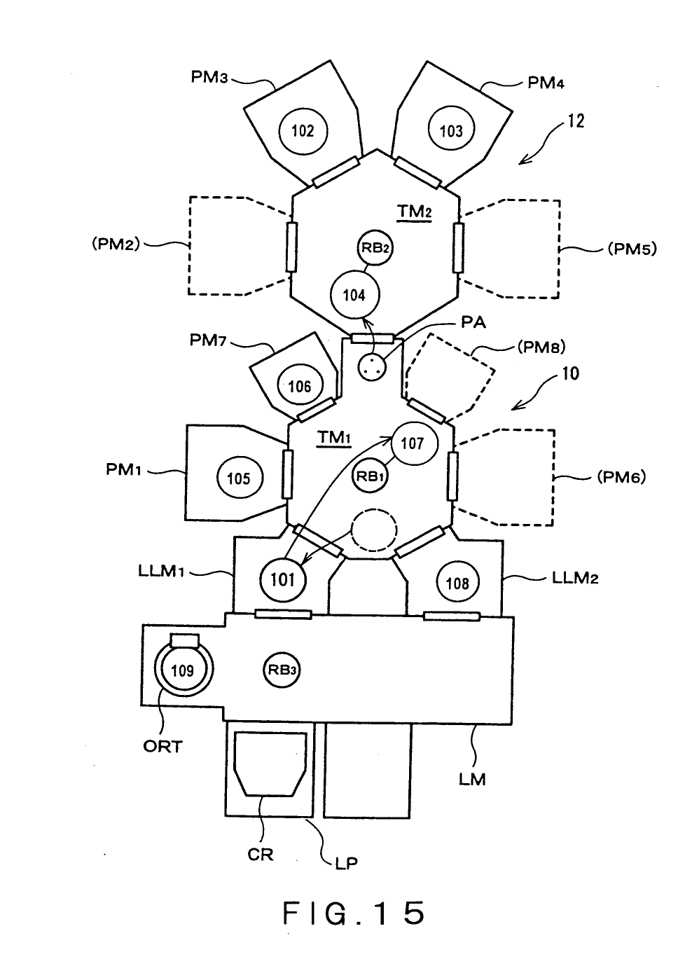

Thereafter, in the second cluster 12, the second vacuum transfer robot RB₂ picks up the forwarding wafer W104 from the pass unit PA; and in the first cluster 10, the first vacuum transfer robot RB₁ performs the pick & place operation for the loadlock module LLM₁ that has completed vacuuming to interchange wafers 107 and 101, as shown in FIG. 15. That is, the first vacuum transfer robot RB₁ picks up the unprocessed wafer W107 from the loadlock module LLM₁ in a reduced pressure state and, in turn, returns the processed wafer W101 back to the loadlock module LLM₁ instead. The processed wafer W101 is cooled by the loadlock module LLM₁ to a set temperature near the room temperature.

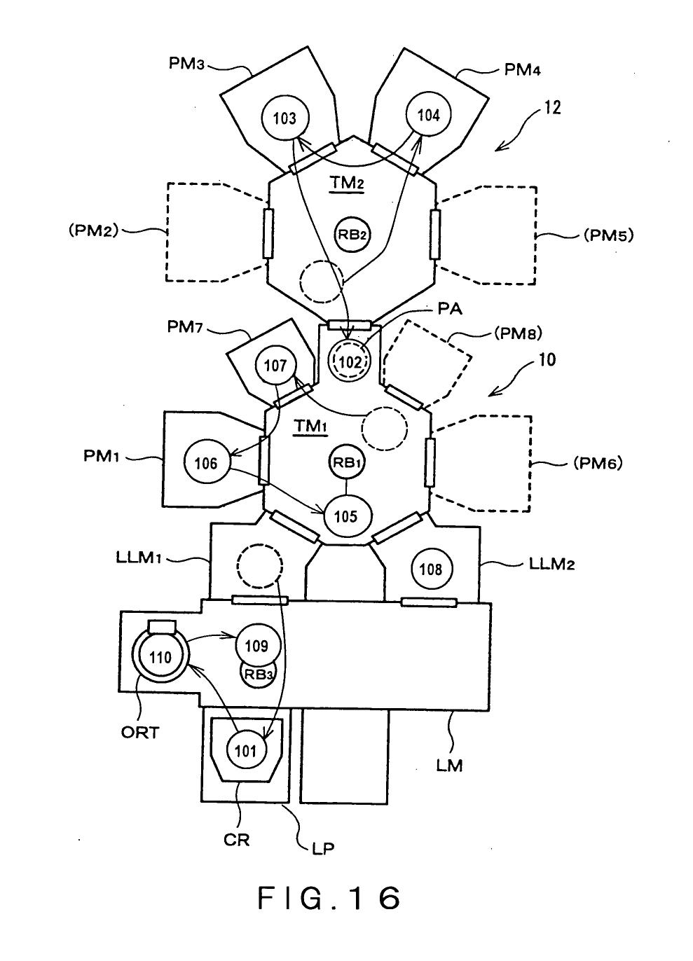

Thereafter, as shown in FIG. 16, the chamber of the loadlock module LLM₁ is changed to the atmospheric pressure state, and the atmospheric transfer robot RB₃ transfers the processed wafer W101 from the loadlock module LLM₁ to the cassette CR of the load ports LP. In the second cluster 12, wafers W103 and W104 are interchanged with each other through the pick & place operation for the process module PM₄ that has completed the TaN/Ta laminated films forming process. Then, at the process module PM3 that has completed the Cu seed layer forming process, wafers W102 and W103 are interchanged through the pick & place operation. The processed wafer W102 unloaded from the process module PM₃ is transferred to the pass unit PA. In the first cluster 10, on the other hand, even if the processed wafer W102 has been transferred to the pass unit PA, it is ignored (that is, the wafer W102 will not picked up immediately) and the forwarding serial transfer operation is performed. That is, the pick & place operation is performed for the process module PM₇ that has completed the degas process to interchange wafers W106 and W107, and then the pick & place operation is performed for the process module PM₁ that has completed the cleaning process to interchange wafers W105 and W106. Then, while holding the wafer W105, unloaded from the process module PM₁, with one transfer arm, the first vacuum transfer robot RB₁ sets the other (empty) transfer arm so as to oppose the returning wafer W102 that has been suspended in the pass unit PA. Although not shown in the drawing, the first vacuum transfer robot RB₁ picks up the returning wafer W102 from the pass unit PA and, in turn, transfers the forwarding wafer W105 to the pass unit PA instead, through the pick & place operation. Then, the first vacuum transfer robot RB₁ performs the pick & place operation for the loadlock module LLM₂ to interchange wafers W108 and W102. That is, the first vacuum transfer robot RB₁ picks up the unprocessed wafer W108 from the loadlock module LLM₂ in a reduced pressure state and, in turn, transfers the processed wafer W102 to the loadlock module LLM₂ instead.

Subsequently, the transfer sequence is repeated in the same procedures as described above. However, almost at the end of the production lot, there is no wafer following the last wafer W125 and therefore an exceptional transfer procedure is used. For example, when the last wafer W125 is unloaded from each process module PM, a sole pick operation is performed but a place operation is not performed. Further, when the third wafer W123 from the last is moved from the process module PM₃ to the pass unit PA as a returning wafer W←, the following wafers W124 and W125 have already been loaded into the process modules PM₄ and PM₃, respectively, in the second cluster 12, and there is no wafer in the transfer path in the first cluster 10. The controller of each module or the host controller (CNTL20) constantly or occasionally monitors the existence and identifies wafers in the transfer paths of each part in the system. Therefore, at the end of the production lot, if it is recognized that there is no wafer in the transfer path in the first cluster 10 when the returning wafer W← is transferred from the second cluster to the pass unit PA, the first vacuum transfer robot RB₁ may immediately pick up the returning wafer W from the pass unit PA and then return it back to the loadlock module LLM₁ (LLM₂) in a reduced pressure state.

As mentioned above, in the present embodiment, when the returning wafer W← to be moved from the second cluster 12 to the first cluster 10 arrives at the pass unit PA, if a forwarding wafer W→ to be transferred to the second cluster 12 exists in the transfer path in the first cluster 10, serial transfer in the first cluster 10 is preferentially performed and then the returning wafer W← is suspended in the pass unit PA until it is interchanged with the forwarding wafer W← that has completed necessary (first phase) processing in the first cluster 10. In view of the situation that the returning wafer W→ is suspended in the pass unit PA, it may be regarded that the transfer cycle time or the transfer tact (transfer interval) be prolonged for the suspended period of time.

However, in the interchange transfer method, each wafer Wᵢ is interchanged with a subsequent wafer Wᵢ₊₁ in the transfer path through the pick & place operation so as to be transferred from each process module PMₙ to the next process module PMₙ₊₁. Therefore, the transfer cycle time or the transfer tact in the system is constrained by a PM cycle time, which means a time period from a point of time when a wafer is loaded into a process module to a point of time when a next wafer is loaded into the same, especially by a maximum PM cycle time. In determining a transfer procedure and a transfer timing, priority should be given to avoidance of increasing of the PM cycle times (especially the maximum PM cycle time). At a point other than a process module in the wafer transfer path in the system, a suspended time corresponding to the difference between the maximum PM cycle time and each of other PM cycle times is generated. Therefore, even if a wafer is suspended at a point other than a process module (including the pass unit PA) for a time period shorter than a certain fixed time, the throughput is not adversely affected. Therefore, giving more priority to serial transfer between process modules than to immediately picking up a wafer from the pass unit PA does not result in the degradation of the throughput, but results in the improvement thereof.

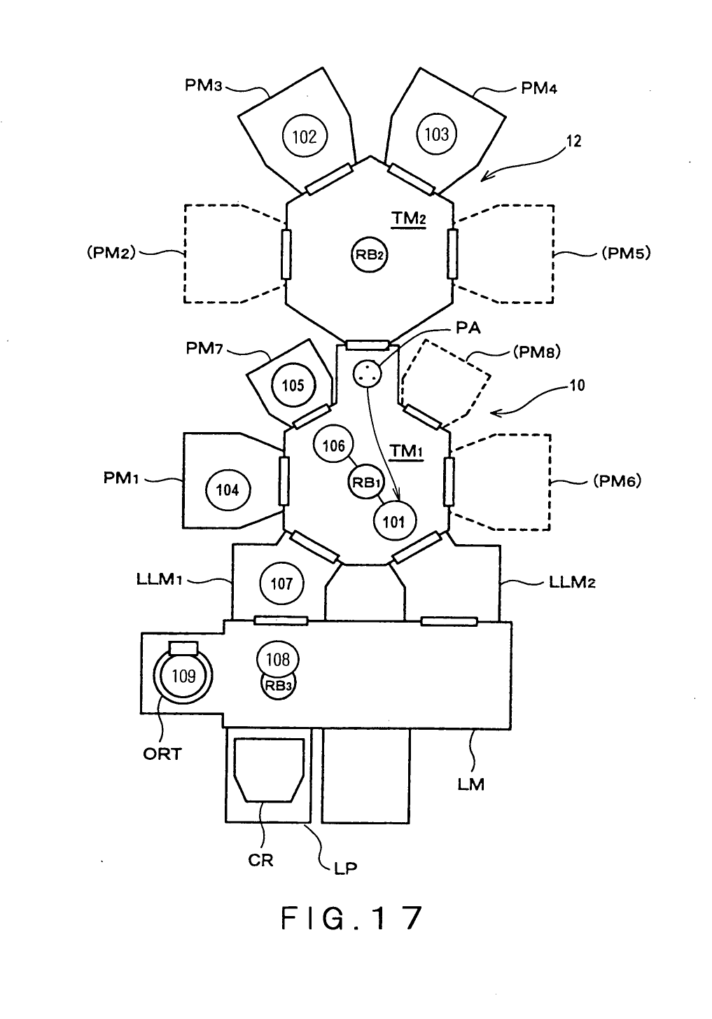

In contrast, in the conventional transfer system, when a returning wafer W← (W101) to be moved from the second cluster 12 to the first cluster 10 is transferred to the pass unit PA, as shown in FIG. 12, the transfer procedure immediately after that timing is as shown in FIGS. 17, 18, and 19. Specifically, as shown in FIG. 17, the first vacuum transfer robot RB₁ of the first cluster 10 picks up the returning wafer W101 from the pass unit PA with an empty transfer arm. In this case, however, even if the loadlock module LLM₁ has completed vacuuming, the first vacuum transfer robot RB₁ holds the returning wafer W101 and the unprocessed wafer W106 at the same time (both transfers arms F_{A} and F_{B} are occupied), making it impossible to perform the pick & place operation. That is, the unprocessed wafer W107 and the returning wafer W101 cannot be interchanged at the loadlock module LLM₁. As a result, the first vacuum transfer robot RB₁ must wait until the empty loadlock module LLM₂ completes vacuuming while holding the returning wafer W101 and the unprocessed wafer W106 at the same time.

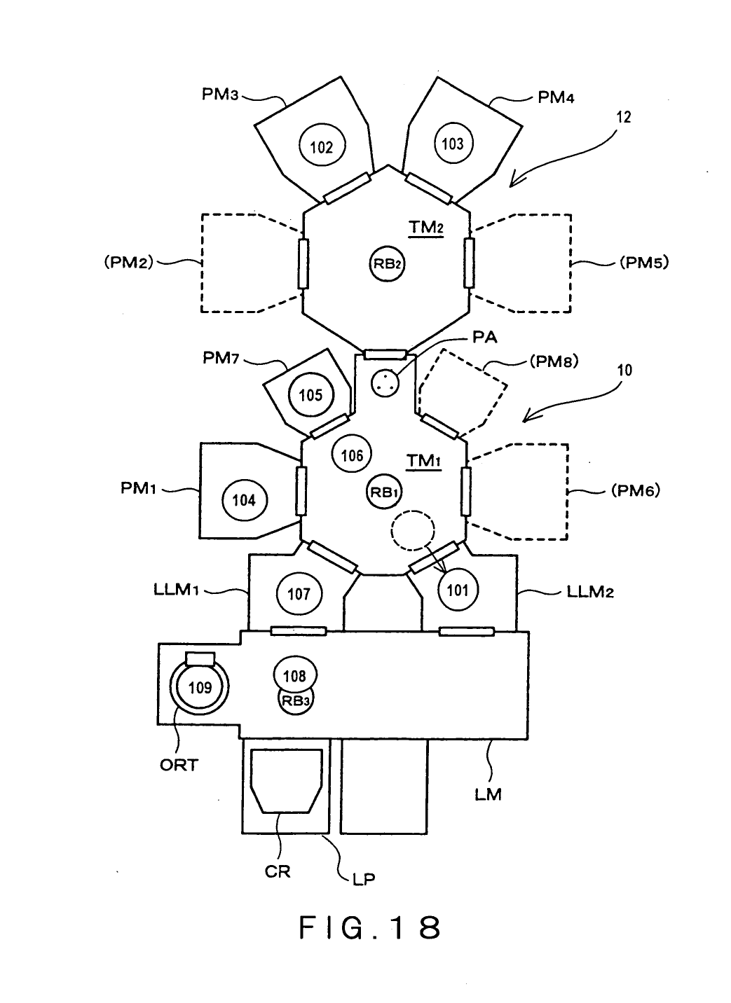

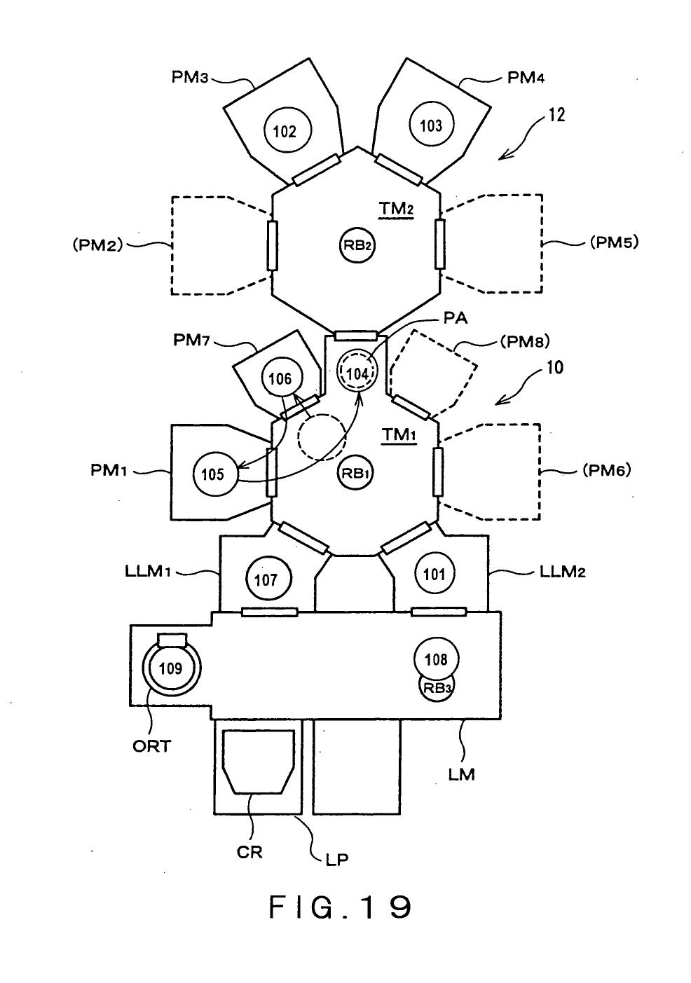

Then, when the loadlock module LLM₂ completes vacuuming, the first vacuum transfer robot RB₁ loads the returning wafer W101 into the lock module LLM₂, as shown in FIG. 18. As a result, one transfer arm is emptied, allowing the pick & place operation. Then, the first vacuum transfer robot RB₁ starts serial transfer in the first cluster 10. As shown in FIG. 19, the first vacuum transfer robot RB₁ performs the pick & place operation for the process module PM₇, which has completed the degas process and is suspended, to interchange wafers W105 and W106; performs the pick & place operation for the process module PM₁, which has completed the cleaning process and is suspended, to interchange wafers W104 and W105 and, in turn, transfers the forwarding wafer W104, unloaded from the process module PM₁, to the pass unit PA.

In this way, in the conventional transfer method, even if the first vacuum transfer robot RB₁ of the first cluster 10 immediately picks up the returning wafer W← transferred from the second cluster 12 to the pass unit PA, the wafer cannot be smoothly transferred to or loaded into the loadlock module LLM₁ (LLM₂) which is the next destination. In addition, serial transfer for the process module PM is deferred and accordingly the PM cycle time (especially the suspended time occupied in the PM cycle time) increases, resulting in an increased average of the transfer cycle time in one production lot.

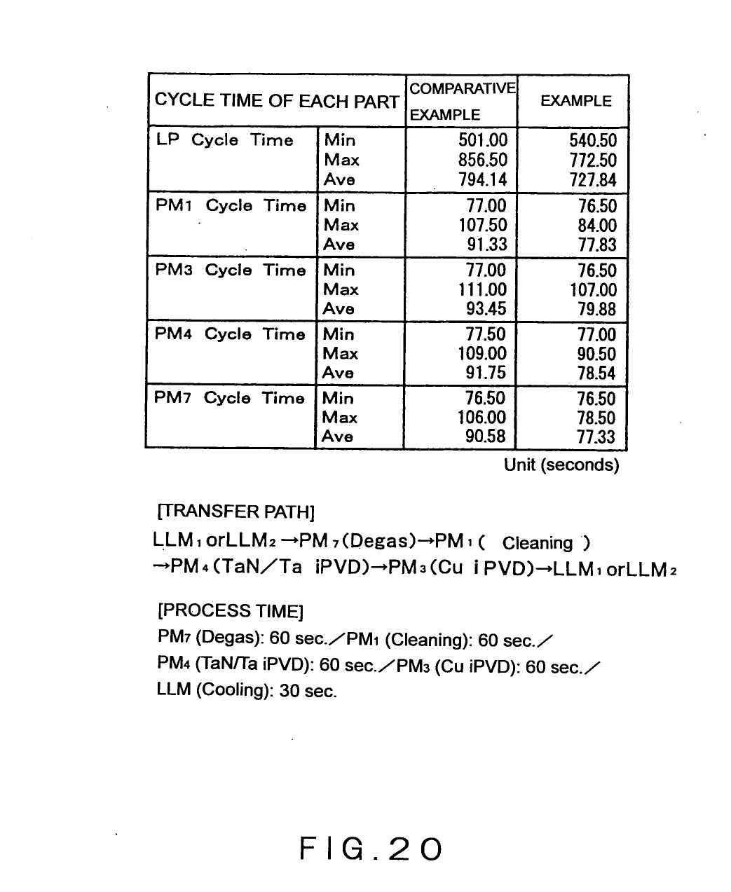

FIG. 20 is a table showing cycle times of each unit and total cycle time of the substrate processing system according to the present embodiment. It compares the transfer procedure of the present invention (especially FIGS. 13, 14, and 15) with that of a comparative example (FIGS. 17, 18, and 19). The table shows the minimum (Min), maximum (Max), and average (Ave) cycle times of each unit in wafer transfer of 25 wafers per lot, obtained through simulation. Here, “LP Cycle Time (LP cycle time)” is a time period from a point of time when each wafer Wᵢ is unloaded from a load port LP to a point of time when it is returned back to the load port LP. “PMₙ Cycle Time (PMₙ cycle time)” (n=1, 3, 4, 7) is a time period from a point of time when each wafer Wᵢ is loaded into each process module PMₙ to a point of time when a following wafer Wᵢ₊₁ is loaded into the same. The process time in each process module PMₙ (n=1, 3, 4, 7) is 60 seconds, and the cooling time in the loadlock module LLM₁ (LLM₂) is 30 seconds. Although the process time is constant (60 seconds), a difference arises in the PMₙ cycle time (PM cycle time) because a difference arises in the transfer or suspended time in one cycle. The cycle time at the end of a production lot is relatively short, and the cycle time in the middle of the production lot is relatively long.

Referring to FIG. 20, each of LP cycle times and minimum (Min) PM cycle times is hardly different between the present invention and the comparative examples because the above cycle times are obtained with the last wafer W125 and there is no situation where a wafer is suspended in the middle of the transfer path. However, the maximum (Max) and average (Ave) cycle times of each unit have been remarkably improved by the present invention, that is, reduced by about 10%. A cluster tool generally performs long-time consecutive processing and therefore the productivity will be remarkably improved only by reducing the transfer cycle time by several percents.

In order to form TaN/Ta laminated films which constitute a barrier layer and a Cu seed layer, through in-line consecutive film forming processes in the copper wiring process employing a copper-plating film, the present embodiment sequentially performs the degas process and the etching process as the first phase processing in the process modules PM₇ and PM₁, respectively, in the first cluster 10, and sequentially performs the TaN/Ta laminated films forming process and the Cu seed layer forming process as second phase processing in the process modules PM₄ and PM₃, respectively, in the second cluster 12. In one modification, in order to perform substantially the same vacuum thin film formation, it is also possible to sequentially perform the etching process, the TaN/Ta laminated films forming process employing an ALD (Atomic Layer Deposition) method, and the degas process as first phase processing in the process modules PM₁, PM₆, and PM₇, respectively, in the first cluster 10; and perform the Cu seed layer forming process employing the iPVD method as second phase processing in the process module PM₃, in the second cluster 12.

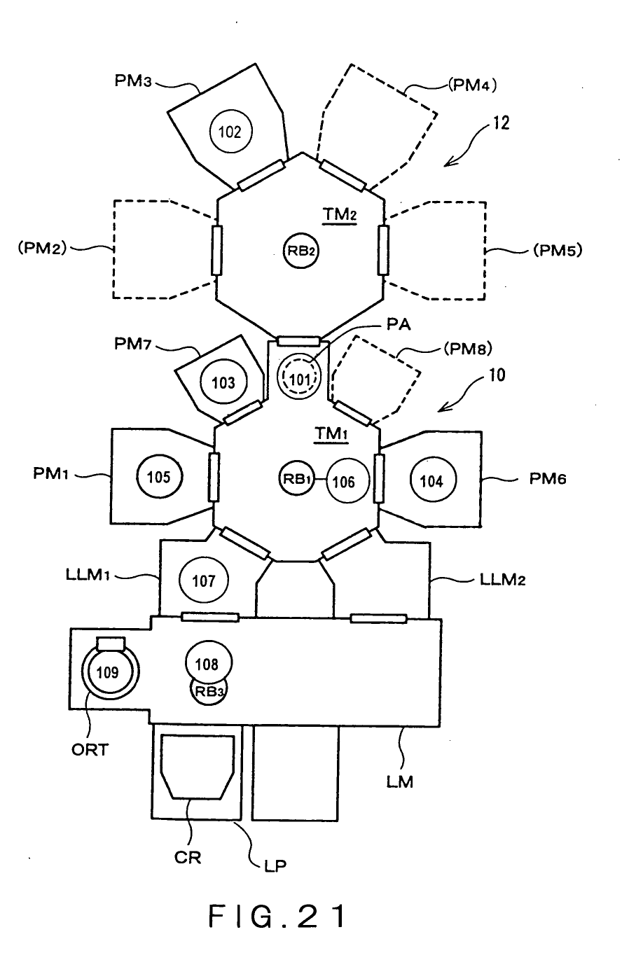

In this case, (intermediate transfer sequence is omitted) as shown in FIG. 21, when the returning wafer W← (W101) from the second cluster 12 to the first cluster 10 is transferred to the pass unit PA, there is one or a plurality of forwarding wafers W in the transfer path in the first cluster 10 except at the end of a production lot. Typically, as shown in FIG. 21, the first vacuum transfer robot RB₁ holds the unprocessed wafer W106 with one transfer arm; the process modules PM₁, PM₆, and PM₇ perform the cleaning process, the TaN/Ta laminated films forming process, and the degas process for wafers W105, W104, and W103, respectively; and one loadlock module LLM₁ containing the unprocessed wafer W107 performs vacuuming. Since the other transfer arm is emptied, the first vacuum transfer robot RB₁ can pick up the returning wafer W101 transferred from the second cluster 12 to the pass unit PA using the emptied transfer arm.

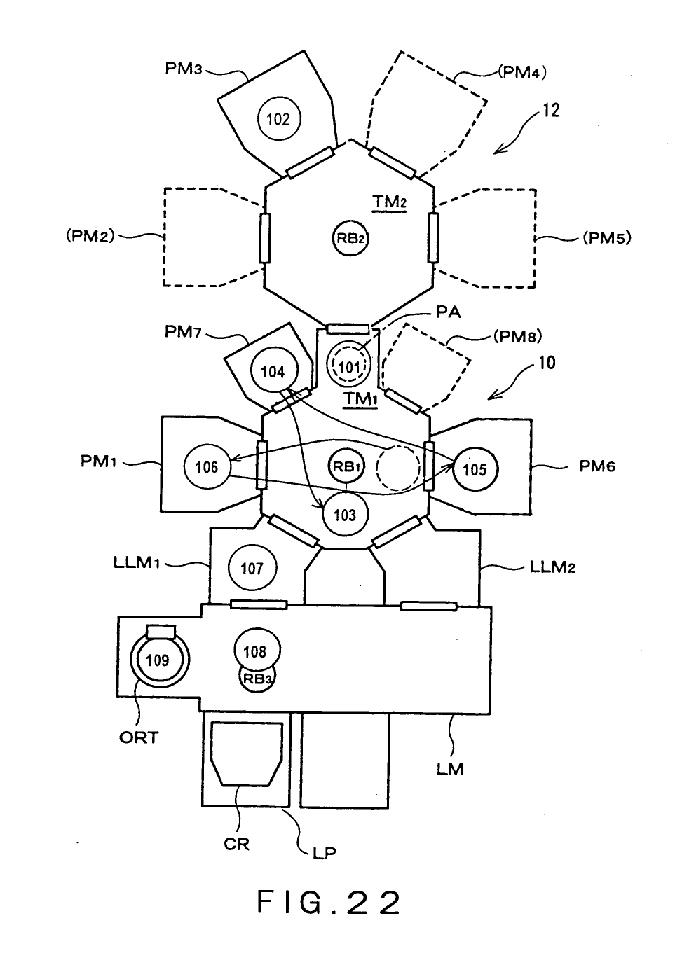

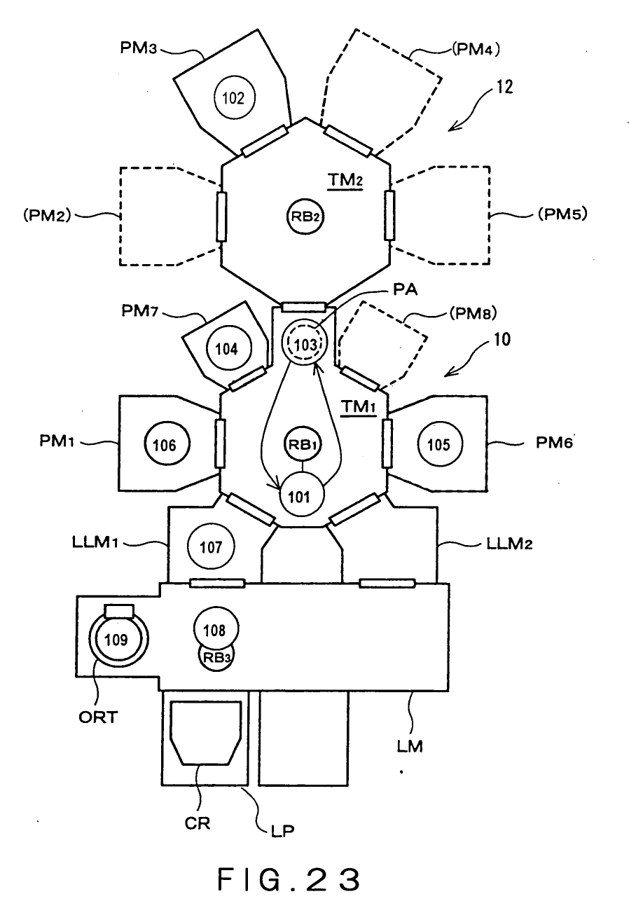

Even in this case, however, in accordance with the present invention, the first vacuum transfer robot RB₁ preferentially performs serial transfer in the first cluster 10 while suspending the returning wafer W101 in the pass unit PA. That is, as shown in FIG. 22, the first vacuum transfer robot RB₁ performs the pick & place operation for the process module PM₁ that has completed the cleaning process to interchange wafers W105 and W106; performs the pick & place operation for the process module PM₆ that has completed the TaN/Ta laminated films forming process to interchange wafers W104 and W105; and performs the pick & place operation for the process module PM₇ that has completed the degas process to interchange wafers W103 and W104. In this way, while holding the wafer W103, unloaded from the process module PM₇, with one transfer arm, the first vacuum transfer robot RB₁ sets the other (empty) transfer arm so as to oppose the returning wafer W101 that has been suspended in the pass unit PA. Then, as shown in FIG. 23, the first vacuum transfer robot RB₁ picks up the returning wafer W101 from the pass unit PA and, in turn, transfers the forwarding wafer W103 to the pass unit PA instead, through the pick & place operation. In this way, giving more priority to wafer interchanging at the process modules PM₁, PM₆, and PM₇ than to picking up the returning wafer W101 from the pass unit PA suits the purpose of improving the throughput for the whole production lot.

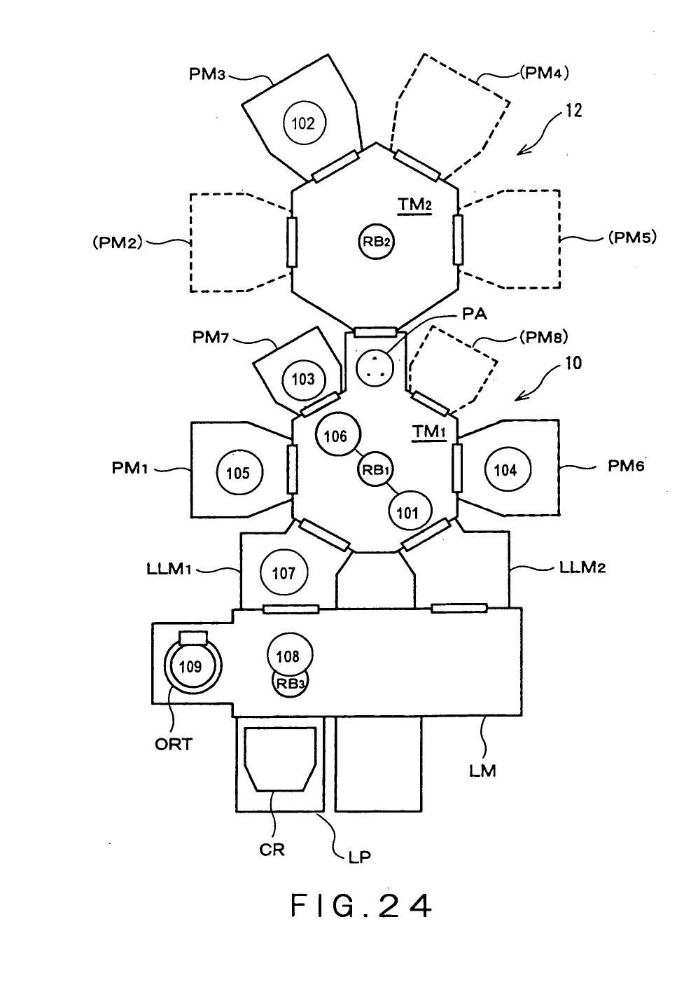

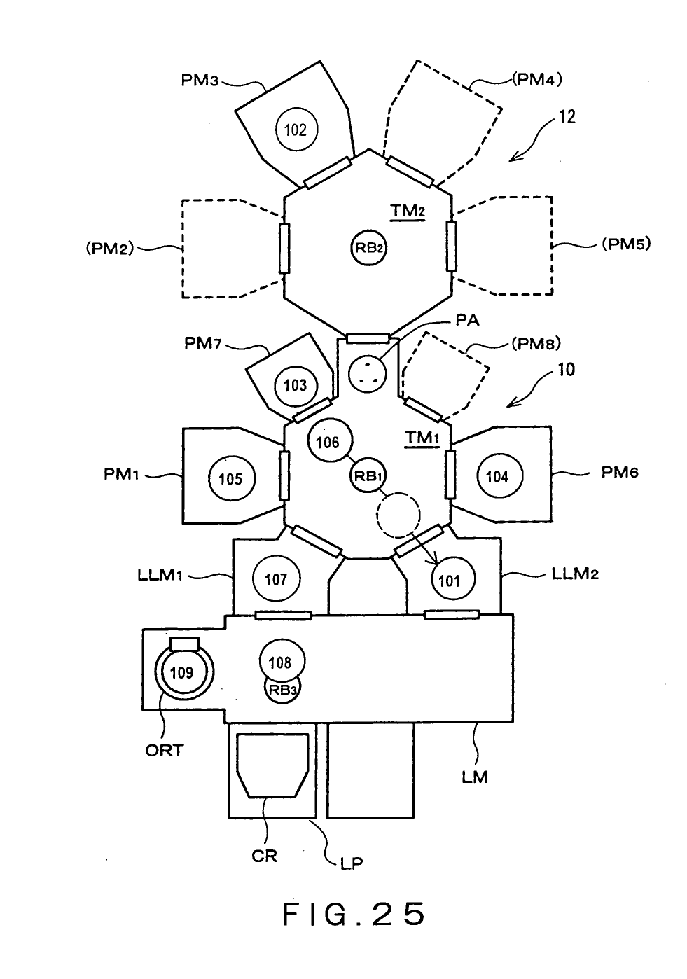

On the other hand, in the conventional transfer method, when the returning wafer W← (W101) to be moved from the second cluster 12 to the first cluster 10 is transferred to the pass unit PA as shown in FIG. 21, the first vacuum transfer robot RB₁ of the first cluster 10 picks up the returning wafer W101 from the pass unit PA with an empty transfer arm, as shown in FIG. 24. Also in this case, however, the unprocessed wafer W107 and the returning wafer W101 cannot be interchanged through the pick & place operation at the loadlock module LLM₁. Therefore, it is necessary for the first vacuum transfer robot RB₁ to hold the returning wafer W101 until the emptied loadlock module LLM₂ completes vacuuming. Thereafter, as shown in FIG. 25, the first vacuum transfer robot RB₁ loads the returning wafer W101 into the loadlock module LLM₂ that has completed vacuuming through a sole place operation and then starts serial transfer in the first cluster 10. In this way, even if the first vacuum transfer robot RB₁ of the first cluster 10 immediately picks up the returning wafer W← transferred from the second cluster 12 to the pass unit PA, it cannot be smoothly transferred to the loadlock module LLM₁ (LLM₂) which is the next destination. In addition, serial transfer or wafer interchange at the process module PM will be deferred, resulting in degradation in the throughput of the whole system or on a production lot basis.

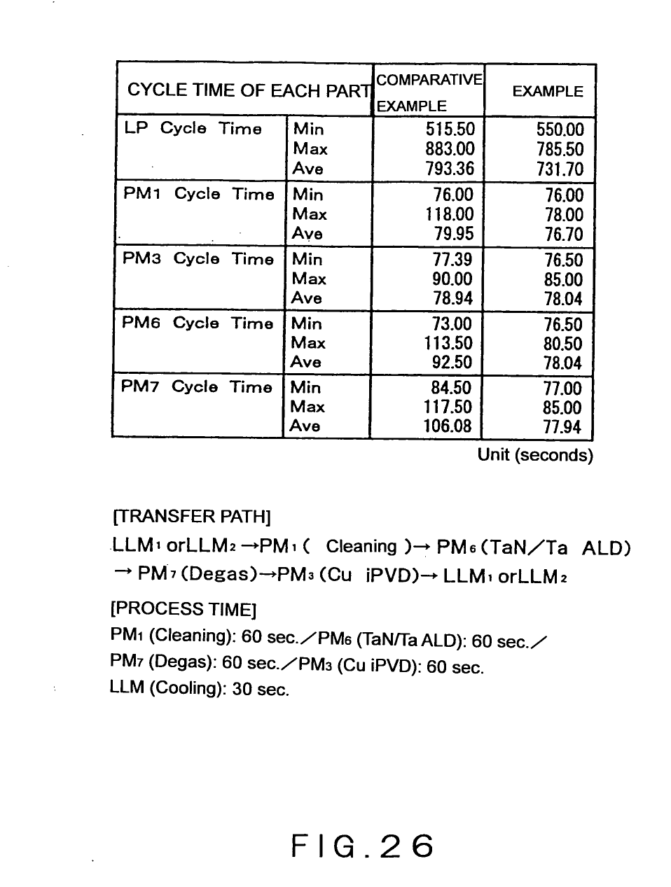

FIG. 26 is a table showing cycle times of each unit and total cycle time according to the second embodiment. It compares the transfer procedure of the present invention (FIGS. 22 and 23) with that of a comparative example (FIGS. 24 and 25). However, the PMₙ cycle time (n=1, 3, 6, 7) is the time period from a point of time when each wafer Wᵢ is loaded into each process module PMₙ to a point of time when the next wafer Wᵢ₊₁ is loaded into the same, i.e., PM cycle time. The process time in each process module PMₙ (n=1, 3, 6, 7) is 60 seconds, and the cooling time in the loadlock module LLM₁ (LLM₂) is 30 seconds. The data of FIG. 25 shows that, also in the present embodiment, the maximum (Max) and average (Ave) cycle times of each unit have been remarkably improved, that is, reduced by about 10%, by the present invention.

The above-mentioned transfer procedure and processing procedure are merely examples of transfer procedure and processing procedure according to the present invention. The transfer procedure and processing procedure according to the present invention are also applicable to a case where desired in-line compound processing is performed by combining any of the process modules PM₁ to PM₈ in relation to the first cluster 10 and the second cluster 12 in any order.

Further, the foregoing embodiment performs the first phase processing in the first cluster 10 and then the second phase processing in the second cluster 12 to directly transfer all the processed wafers that completed the second phase processing from the pass unit PA to the loadlock module LLM₁ (LLM₂). In the present invention, however, such a transfer sequence is an example and therefore it is also possible, for example, to transfer a wafer that completed the second phase processing in the second cluster 12 from the pass unit PA to a remaining process module PM in the first cluster 10. Further, it is also possible to perform a transfer sequence of compound processing for performing the first phase processing in the second cluster 12 and then the second phase processing in the first cluster 10, and a transfer sequence of compound processing for performing the first phase processing in the second cluster 12, the second phase processing in the first cluster 10, and then the third phase processing in the second cluster 12.

Further, in the foregoing embodiment, a case where the first vacuum transfer robot RB₁ of the first cluster 10 picks up the wafer W transferred to the pass unit PA by the second vacuum transfer robot RB₂ of the second cluster 12 has been explained. However, the present invention is also applicable to a opposite case where the second vacuum transfer robot RB₂ of the second cluster 12 picks up the wafer W transferred to the pass unit PA by the first vacuum transfer robot RB₁ of the first cluster 10. That is, in this case, transfer control is performed such that the wafer W transferred from the first vacuum transfer robot RB₁ to the pass unit PA is suspended therein until the second vacuum transfer robot RB₂ interchanges a wafer, which has completed one or series of processes in the process modules in the second cluster 12 and is forwarding to the first cluster 10, with that wafer in the pass unit PA.

The substrate processing system according to the present invention is not limited to a processing system of a vacuum system like the above-mentioned embodiment, but also applicable to a system of a partially or entirely atmospheric system. A process object in the present invention is not limited to semiconductor wafers. Process objects include various substrates for flat panel display devices, photomasks, CD substrates, printed circuit boards, and the like.

1. A substrate processing system wherein:
said system is provided with a first multi-chamber apparatus and a second multi-chamber apparatus which are connected in series;
the first multi-chamber apparatus includes a first transfer mechanism, a first group of process modules arranged in an surrounding area of the first transfer mechanism, and an interface module disposed in the surrounding area of the first transfer mechanism to transfer process objects between the first multi-chamber apparatus and an exterior thereof;
the second multi-chamber apparatus includes a second transfer mechanism, and a second group of process modules arranged in an surrounding area of the second transfer mechanism;
a relay unit is disposed between the first transfer mechanism and the second transfer mechanism to temporarily keep a process object in order to transfer the process object between the first transfer mechanism and the second transfer mechanism; and
said substrate processing system is further provided with a controller, which is configured to control the first and second transfer mechanisms such that the first and second transfer mechanisms sequentially transfers each process object to process modules of the first and second groups according to a predetermined process sequence, and such that, at each process module of the first and second groups, the first and second transfer mechanisms respectively carry a process object, which has been processed in that process module, out of that process module and carry another process object, which is to be processed next in that process module, into that process module instead;
characterized in that controller is configured to control the first transfer mechanism such that, when a first process object having been subjected to predetermined process or processes in the second multi-chamber apparatus is carried into the relay unit by the second transfer mechanism, if there is established a state where a second process object, which is to be carried from the first multi-chamber apparatus into the second multi-chamber apparatus next, can not be carried into the relay unit, the first process object is kept suspended in the relay unit until there is established a state where the second process object can be carried into the relay unit, and thereafter the first transfer mechanism carries the first process object out of the relay unit and carries the second process object into the relay unit instead.

2. The substrate processing system according to claim 1, wherein the controller is configured to monitor whether or not any process object exists on any transfer path extending from the interface module through the process modules of the first group to the relay unit, and is configured to control the first transfer mechanism such that, if there exists no process object on the transfer path at a point of time when the second transfer mechanism transfers the first process object to the relay unit, the first transfer mechanism immediately carries the first process object located in the relay unit out of the relay unit.

3. The substrate processing system according to claim 1, wherein:
the first transfer mechanism has two transfer arms that are capable of moving into and out of each of the process modules of the first group; and
the controller is configured to control the first transfer mechanism such that, when, at each process module of the first group, the first transfer mechanism carries a process object, which has been processed in that process module, out of that process module and carries another process object, which is to be processed in that process module next, into that process module instead, the process object which has been processed in that process module is carried out of that process module by using one of the two transfer arm, and subsequently said another process object is carried into that process module by using the other transfer arm.

4. The substrate processing system according to claim 3, wherein:
the two arms of the first transfer mechanism are also configured to be capable of transferring a process object to and from the relay unit; and
the controller is configured to control the first transfer mechanism such that, when the first transfer mechanism carries the first process object out of the relay unit and carries the second process object into the relay unit instead, the first process object is carried out of the relay unit by using one of the two transfer arms, and then the second process object is carried into the relay unit by using the other transfer arm.

5. The substrate processing system according to claim 3, wherein:
the two arms of the first transfer mechanism are also configured to be capable of transferring a process object to and from the interface module; and
the controller is configured to control the first transfer mechanism such that a unprocessed process object is carried out of the interface module by using one of the two transfer arms, and a process object, which has been subjected to all processes which should be performed in the first and second multi-chamber apparatuses, is successively carried into the interface module.

6. The substrate processing system according to claim 1, wherein the controller is configured to control the first transfer mechanism such that the first transfer unit transfers the first process object, which is carried out of the relay unit by the first transfer mechanism, directly to the interface module.

7. A substrate processing system wherein:
said system is provided with a first multi-chamber apparatus and a second multi-chamber apparatus which are connected in series;
the first multi-chamber apparatus includes a first transfer mechanism, a first group of process modules arranged in an surrounding area of the first transfer mechanism, and an interface module disposed in the surrounding area of the first transfer mechanism to transfer process objects between the first multi-chamber apparatus and an exterior thereof;
the second multi-chamber apparatus includes a second transfer mechanism, and a second group of process modules arranged in an surrounding area of the second transfer mechanism;
a relay unit is disposed between the first transfer mechanism and the second transfer mechanism to temporarily keep a process object in order to transfer the process object between the first transfer mechanism and the second transfer mechanism; and
said substrate processing system is further provided with a controller, which is configured to control the first and second transfer mechanisms such that the first and second transfer mechanisms sequentially transfers each process object to process modules of the first and second groups according to a predetermined process sequence, and such that, at each process module of the first and second groups, the first and second transfer mechanisms respectively carry a process object, which has been processed in that process module, out of that process module and carry another process object, which is to be processed next in that process module, into that process module instead;
characterized in that controller is configured to control the second transfer mechanism such that, when a first process object having been subjected to predetermined process or processes in the first multi-chamber apparatus is carried into the relay unit by the first transfer mechanism, if there is established a state where a second process object, which is to be carried from the second multi-chamber apparatus into the first multi-chamber apparatus next, can not be carried into the relay unit, the first process object is kept suspended by in the relay unit until there is established a state where the second process object can be carried into the relay unit, and thereafter the second transfer mechanism carries the first process object out of the relay unit and carries the second process object into the relay unit instead.

8. The substrate processing system according to claim 7, wherein the controller is configured to monitor whether or not any process object exists on any transfer path extending from the relay unit through the process modules of the second group back to the relay unit, and is configured to control the second transfer mechanism such that, if there exists no process object on the transfer path at a point of time when the first transfer mechanism transfers the first process object to the relay unit, the second transfer mechanism immediately carries the first process object located in the relay unit out of the relay unit.

9. The substrate processing system according to claim 7, wherein:
the second transfer mechanism has two transfer arms that are capable of moving into and out of each of the process modules of the second group; and
the controller is configured to control the second transfer mechanism such that, when, at each process module of the second group, the second transfer mechanism carries a process object, which has been processed in that process module, out of that process module and carries another process object, which is to be processed in that process module next, into that process module instead, the process object which has been processed in that process module is carried out of that process module by using one of the two transfer arm, and subsequently said another process object is carried into that process module by using the other transfer arm.

10. The substrate processing system according to claim 9, wherein:
the two arms of the second transfer mechanism are also configured to be capable of transferring a process object to and from the relay unit; and
the controller is configured to control the second transfer mechanism such that, when the second transfer mechanism carries the first process object out of the relay unit and carries the second process object into the relay unit instead, the first process object is carried out of the relay unit by using one of the two transfer arms, and then the second process object is carried into the relay unit by using the other transfer arm.

11. The substrate processing system according to claim 1 or 7, wherein:
the first transfer mechanism and the second transfer mechanism are disposed within a first vacuum transfer chamber and a second vacuum transfer chamber, respectively;
the relay unit is disposed adjacent to a connection between the first vacuum transfer chamber and the second vacuum transfer chamber;
each of the process modules of the first group has a vacuum process chamber which is connected to the first vacuum transfer chamber via a gate valve;
each of the process modules of the second group has a vacuum process chamber which is connected to the second vacuum transfer chamber via a gate valve;
the interface module is connected to the first vacuum transfer chamber via a gate valve, and has a loadlock chamber which is configured to be capable of selectively switching between an atmospheric-pressure state and a reduced pressure state to temporarily keep a process object to be transferred between an atmospheric-pressure space and a reduced-pressure space;
the first transfer mechanism is configured to move within in the first vacuum transfer chamber of a reduced pressure to access the vacuum chambers of the process modules of the first group, the relay unit and the loadlock chamber, in order to transfer process objects; and
the second transfer mechanism is configured to move within the second vacuum transfer chamber of a reduced pressure to access the vacuum chambers of the process modules of the second group, the relay unit, in order to transfer process objects.

12. The substrate processing system according to claim 11, wherein:
the first vacuum transfer chamber and the second vacuum transfer chamber are connected with each other via a gate valve.

13. The substrate processing system according to claim 11, further comprising:
a load port that supports a cassette, which is capable of containing a plurality of process objects, under an atmospheric pressure;
an atmospheric transfer module, which is connected to or placed adjacent to the load port, and which is connected to the loadlock module via a door valve; and
a third transfer mechanism disposed in the atmospheric transfer module to transfer process objects between a cassette placed on the load port and the loadlock module.

14. The substrate processing system according to claim 11, wherein:
at least one the process modules of the first and second groups is a film-forming module that forms a thin film on a process object under a reduced pressure.
